(19) United States
(12) Patent Application Publication
(10) Pub. No.: US 2023/0407498 A1
(43) Pub. Date: Dec. 21, 2023

(54) WATER SPLITTING DEVICE PROTECTION

(71) Applicant: The Regents of the University of Michigan, Ann Arbor, MI (US)

(72) Inventors: Zetian Mi, Ann Arbor, MI (US); Srinivas Vanka, Ann Arbor, MI (US); Baowen Zhou, Ann Arbor, MI (US)

(21) Appl. No.: 18/034,217

(22) PCT Filed: Oct. 27, 2021
(86) PCT No.: PCT/US2021/056804

§ 371 Date: Apr. 27, 2023

Related U.S. Application Data
(60) Provisional application No. 63/116,437, filed on Nov. 20, 2020.
(60) Provisional application No. 63/106,350, filed on Oct. 27, 2020.

(51) Int. Cl. C25B 11/067; C25B 11/081; C25B 11/02; C25B 11/053; C25B 11/087; C25B 9/50; C30B 23/02; C30B 29/40; C23C 18/14; C23C 16/40; C23C 16/455; C23C 28/00

(52) U.S. Cl. CPC C25B 11/067; C25B 11/081; C25B 11/02; C25B 11/053; C25B 11/087; C25B 9/50; C23C 28/32; C30B 29/403; C23C 18/143; C23C 16/403; C23C 16/45525; C23C 28/345; C30B 23/02

(57) ABSTRACT

A device includes a substrate having a surface, an array of conductive projections supported by the substrate and extending outward from the surface of the substrate, a plurality of catalyst nanoparticles disposed over the array of conductive projections, and an oxide layer covering the plurality of catalyst nanoparticles and the array of conductive projections. The oxide layer has a thickness on the order of a size of each catalyst nanoparticle of the plurality of catalyst nanoparticles.

### CROSS-REFERENCES TO RELATED APPLICATIONS

This application claims the benefit of U.S. provisional application entitled “Water Splitting Device Protection,” filed Nov. 20, 2020, and assigned Ser. No. 63/116,437, and U.S. provisional application entitled “Water Splitting Photoelectrode Protection,” filed Oct. 27, 2020, and assigned Ser. No. 63/106,350, the entire disclosures of which are hereby expressly incorporated by reference.

### STATEMENT REGARDING FEDERALLY SPONSORED RESEARCH OR DEVELOPMENT

This invention was made with government support under Grant No. DE-EE0008086 awarded by the Department of Energy. The government has certain rights in the invention.

### BACKGROUND OF THE DISCLOSURE

### Field of the Disclosure

The disclosure relates generally to photoelectrodes, photocatalytic devices, and other devices for hydrogen evolution via water splitting and/or other reactions.

### Brief Description of Related Technology

Photoelectrochemical (PEC) solar water splitting is one of the clean and sustainable approaches to convert the two most abundant natural resources on earth, i.e., sunlight and water, into high calorific value, storable and clean chemical fuels such as hydrogen (H₂). To that end, efforts have been made to develop high efficiency, durable, and cost-effective photoelectrode materials using industry-ready semiconductors for large-scale implementation of PEC devices. To date, high efficiency photoelectrodes have been demonstrated using only a few semiconductors, including Si and III-V compound semiconductors, which, however, suffer from poor stability due to chemical and photochemical corrosion. Compared to photovoltaic electrolyser (PV-EL) devices, the light absorber of PEC devices is often in direct contact with electrolyte, leading to more rapid degradation. The corrosion of semiconductors is influenced by many factors, including intensity of light illumination, biasing conditions, catalyst, surface passivation, semiconductor electronic band structure, electrolyte composition, and the interfaces of semiconductor/electrolyte as well as catalyst/electrolyte. These factors can be potentially addressed by exploring thermodynamic and kinetic protection schemes.

Gerischer's model describes the thermodynamic considerations for photo-corrosion of a photoelectrode. To avoid competition between cathodic and anodic photo-corrosion of photoelectrode with the hydrogen evolution reaction (HER) and the oxygen evolution reaction (OER), respectively, it is useful that the photoelectrodes satisfy the basic criteria: ϕ_{corr}^{h}<E_{anodic} (1.23 V vs. RHE) and ϕ_{corr}^{e}>E_{cathodic} (0 V vs. RHE), where ϕ_{corr}^{e} is the energy level for the cathodic corrosion reaction of semiconductor, and ϕ_{corr}^{h} is the energy level for the anodic corrosion reaction of semiconductor. Previous studies have shown that it is difficult to find an ideal semiconductor material that can satisfy both thermodynamic requirements simultaneously. Si can be easily oxidized under anodic conditions but is expected to be thermodynamically stable under cathodic conditions. Other studies, however, suggested that Si may also be oxidized into an insulating oxide even under cathodic conditions, which leads to poor stability. Group III-V compounds, such as GaAs, often go through a chemical corrosion reaction due to accumulation of surface hole concentration in dark and light.

Various protection schemes have been developed to enhance the stability of photoelectrodes. Kinetic protection for a given photoelectrode is possible by using a synergetic combination of a stable surface protection layer and a highly active co-catalyst. The first generation of photoelectrodes often relied on coupling with highly active catalysts, illustrated in Part A of FIG. 9, which can improve stability due to excellent reaction kinetics and more efficient charge carrier extraction. Recent studies showed that hematite (α-Fe₂O₃) and bismuth vanadate (BiVO₄) with a NiFe co-catalyst exhibited a high level of stability with efficiencies reaching their theoretical maximum values. Extensive studies have also been performed with the use of Pt, MoS₂, and NiMo, as both protection layers and co-catalysts for HER.

To further improve device stability, a second generation of photoelectrodes, illustrated in Part B of FIG. 9, employ relatively thick metal oxides, such as TiO₂, Al₂O₃, and IrOx, as passivation layers, in addition to the use of suitable co-catalysts. Although the stability of these devices has improved, one major issue is the loss of photocurrent, due to poor charge transfer and, in some cases, undesired light absorption by the protection layers. One of the best-performing photocathodes, in terms of stability, was reported by Bae et al., “Durability Testing of Photoelectrochemical Hydrogen Production under Day/Night Light Cycled Conditions,” ChemElectroChem, Vol. 6, p. 106-109 (2019), using a Pt co-catalyst and 100 nm thick TiO₂ for metal oxide semiconductor junctions Si photocathode, which exhibits stable operation for about 82 days with a photocurrent density (≤23 mA/cm²).

### SUMMARY OF THE DISCLOSURE

In accordance with one aspect of the disclosure, a device includes a substrate having a surface, an array of conductive projections supported by the substrate and extending outward from the surface of the substrate, a plurality of catalyst nanoparticles disposed over the array of conductive projections, and an oxide layer covering the plurality of catalyst nanoparticles and the array of conductive projections. The oxide layer has a thickness on the order of a size of each catalyst nanoparticle of the plurality of catalyst nanoparticles.

In accordance with another aspect of the disclosure, a method for fabricating a device includes providing a substrate having a surface, growing an array of nanowires on the surface of the substrate such that each nanowire of the array of nanowires extends outward from the surface of the substrate, each nanowire of the array of nanowires having a semiconductor composition, depositing a plurality of catalyst nanoparticles across the array of nanowires; and covering the plurality of catalyst nanoparticles and the array of nanowires with an oxide layer. The oxide layer has a thickness on the order of a size of each catalyst nanoparticle of the plurality of catalyst nanoparticles.

In accordance with yet another aspect of the disclosure, a device includes a substrate including a plurality of semiconductor layers and a surface, the plurality of semiconductor layers being doped to establish a junction for charge carriers photogenerated in the substrate, and an array of nanostructures supported by the substrate and extending outward from the surface of the substrate, each nanostructure of the array of nanostructures including a plurality of semiconductor segments. The plurality of semiconductor segments include a first segment having a semiconductor composition configured for photogeneration of charge carriers, and second and third segments configured to establish a tunnel junction. A surface of the plurality of semiconductor segments includes nitrogen.

In accordance with still another aspect of the disclosure, a method for fabricating a device includes forming a structure on a semiconductor substrate of the device, the structure having a surface configured to facilitate a reaction, and forming a layer on the surface, the layer including nitrogen.

In accordance with yet another aspect of the disclosure, a device includes a semiconductor structure having a surface, a catalyst arrangement disposed on the surface, and a conformal protection layer covering the catalyst arrangement. The conformal protection layer has a thickness that allows charge carrier transfer to occur at the catalyst arrangement.

In connection with any one of the aforementioned aspects, the electrodes, devices, systems, and/or methods described herein may alternatively or additionally include or involve any combination of one or more of the following aspects or features. The thickness of the oxide layer falls within a range of about 1 nm to about 2 nm. The size of each catalyst nanoparticle of the plurality of catalyst nanoparticles falls in a range from about 2 nm to about 3 nm. The oxide layer includes aluminum oxide. The oxide layer conformally covers the plurality of catalyst nanoparticles and the array of conductive projections. Each conductive projection of the array of conductive projections includes a plurality of indium gallium nitride (InGaN) segments. The plurality of InGaN segments includes a first segment having a compound semiconductor composition configured for photogeneration of charge carriers, and second and third segments configured to establish a tunnel junction. The substrate includes a plurality of silicon layers. The plurality of silicon layers are doped to establish a junction for charge carriers photogenerated in the substrate. The plurality of InGaN segments further includes a fourth segment between the tunnel junction and the substrate. Each conductive projection of the array of conductive projections has a semiconductor composition. The semiconductor composition of each conductive projection of the array of conductive projections is terminated with nitrogen along surfaces of the conductive projection. Each conductive projection of the array of conductive projections includes indium gallium nitride doped with magnesium. Each conductive projection of the array of conductive projections includes a nanowire. Each catalyst nanoparticle of the plurality of catalyst nanoparticles includes platinum. Covering the plurality of catalyst nanoparticles and the array of nanowires includes depositing aluminum oxide via atomic layer deposition. Depositing the plurality of catalyst nanoparticles includes implementing a photo-deposition procedure with platinum. Growing the array of nanowires includes implementing a molecular beam epitaxy (MBE) procedure with N-rich conditions. Growing the array of nanowires includes adjusting a parameter of the MBE procedure to vary an indium incorporation level in the semiconductor composition such that each nanowire of the array of nanowires includes a plurality of indium gallium nitride (InGaN) segments. The plurality of InGaN segments includes a first segment configured to absorb visible light, and second and third segments configured to establish a tunnel junction. The substrate includes a plurality of silicon layers. The plurality of silicon layers are doped to establish a junction. The surface of the plurality of semiconductor segments is nitrogen-terminated. The device further includes a plurality of catalyst nanoparticles disposed over the array of nanostructures. The device further includes an aluminum oxide layer covering the plurality of catalyst nanoparticles and each nanostructure of the array of nanostructures. The aluminum oxide layer has a thickness on the order of a size of each catalyst nanoparticle of the plurality of catalyst nanoparticles. The plurality of semiconductor segments further includes a fourth segment between the tunnel junction and the substrate. Each semiconductor segment of the plurality of semiconductor segments includes InGaN. Forming the layer includes implementing a reaction to form the layer spontaneously. Forming the layer includes depositing the layer on the structure. Forming the structure includes depositing a layer on a substrate, the layer being configured to facilitate the reaction. The conformal protection layer includes an oxide.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a schematic view and block diagram of an electrochemical system having a photocathode with an array of nanostructures having a protection arrangement for stable hydrogen evolution via water splitting in accordance with one example.

FIG. 2 is a flow diagram of a method of fabricating of a photocathode having a protection arrangement in accordance with one example.

FIG. 3 depicts a graphical comparison of photoelectrode performance and stability for a number of different types of photoelectrodes, along with a graphical plot of J-V simulation data for two examples, and a schematic view of a photocathode having a catalyst protection arrangement in accordance with one example.

FIG. 4 depicts a scanning electron microscopy (SEM) image of a photoelectrode in accordance with one example, along with a graphical plot of photoluminescence data for one example, a diagrammatic view of an energy band diagram of a photo electrode in accordance with one example, and a graphical plot of XPS measurements for one example.

FIG. 5 depicts a schematic view of a nanowire of a photoelectrode in accordance with one example, as well as a STEM-HAADF image of a segment of one example of a nanowire, a STEM image of a tunnel junction region of the nanowire, a STEM-HAADF and EELS mapping image showing a catalyst arrangement of the nanowire.

FIG. 6 depicts graphical plots of three-electrode linear scan voltammogram (LSV) and chopped J-V curve data for photoelectrochemical performance of photoelectrodes in accordance with two examples.

FIG. 7 depicts graphical plots of impedance spectroscopy data for photoelectrodes in accordance with two examples.

FIG. 8 depicts of hydrogen evolution and stability data for a photoelectrode in accordance with one example.

FIG. 9 depicts schematic views of several photocathodes for water splitting, including a photocathode without a surface protection arrangement (part (a)), a photocathode with a conventional thick surface protection layer (part (b)), and a photocathode with a multifunctional protection layer (part (c)) in accordance with one example.

FIG. 10 depicts an SEC image of a GaN nanowires on a silicon substrate, as well as a STEM image of Pt nanoparticles on a GaN nanowire (with an HDAAD image inset), and graphical plots of J-V curves and a high applied bias photon-to-current efficiency (ABPE) of a platinized GaN nanowire photocathode.

FIG. 11 depicts graphical plots of long term current density measurements for a platinized GaN nanowire photocathode, as well as a graphical plot of Vₒₙ variations.

FIG. 12 depicts SEM and STEM images of a platinized GaN nanowire photocathode after a stability experiment (with an HDAAD image inset).

FIG. 13 depicts graphical plots of hydrogen production efficiency and stability test data for a platinized GaN nanowire photocathode.

FIG. 14 depicts atomic force microscope (AFM) images of nearly coalesced GaN nanostructures on a silicon substrate before and after a stability test.

The embodiments of the disclosed devices, systems, and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Photoelectrochemical, photocatalytic, and other systems and devices (e.g., photoelectrodes) for water splitting and other chemical reactions are described. Methods of fabricating the devices (e.g., photoelectrodes or photocatalytic devices) are also described. The water splitting and other chemical reactions may be solar driven (e.g., solar water splitting). The disclosed devices, systems and methods may thus be considered to implement artificial photosynthesis in some cases. In some cases, the disclosed devices, systems and devices include an array of conductive projections, such as nanowires or other nanostructures. Each nanostructure or other conductive projection may establish a structure to support and otherwise provide catalysts for the water splitting or other chemical reaction. In other cases, the disclosed devices may be configured as a planar structure. For instance, the functionality of the nanostructures may be provided instead by a number of planar (e.g., non-patterned) layers supported by a substrate. In such cases, one or more of the layers may include a distribution of catalyst nanoparticles.

As described herein, one or more aspects of the disclosed devices, systems and methods are directed to passivation or other protection of the catalysts and/or other elements of the disclosed photoelectrodes (e.g., photocathodes), photocatalytic devices, or other devices. The protection may be provided by a thin, conformal layer (e.g., a conformal oxide layer). In some cases, the conformal layer is composed of aluminum oxide, but additional or alternative oxides may be used. In nanoparticle catalyst cases, the conformal layer may have a thickness on the order of the size of each catalyst nanoparticle. The thin nature of the conformal layer is configured such that the layer does not inhibit the tunneling or other transfer of charge carriers, e.g., from the photoelectrode structure(s) to reaction sites along the photoelectrode. The conformal layer is nonetheless still sufficiently thick to cover, and therefore protect, the catalyst arrangement. For instance, protection of the catalyst nanoparticles and/or other surface passivation is thus provided despite the thin nature of the oxide or other conformal layer.

Alternative or additional surface protection is provided by a nitrogen-based surface of the disclosed photoelectrode. In cases involving an array of nanostructures, each nanostructure may be composed of, or otherwise include, a compound semiconductor that establishes the nitrogen-based surface. For instance, the nanostructures may be composed of GaN in an arrangement in which the surface is nitrogen-terminated. Alternatively or additionally, the disclosed photoelectrodes may have one or more surfaces on which a nitrogen or other nitrogen-based layer is disposed.

In some cases, the surface protection schemes described herein are provided in conjunction with photoelectrodes, photocatalytic devices, or other devices having a multiple (e.g., double) junction configuration. In such cases, one of the junctions may be provided via a doped substrate. For instance, silicon and/or other semiconductors may be configured for photogeneration of charge carriers. Another junction may be provided via the array of nanostructures. For instance, each nanostructure may include multiple compound semiconductor segments, some of which are configured to establish a tunnel junction. The segments may include a segment between the tunnel junction and the substrate to establish a defect-free structure or otherwise reduce the number of defects.

Although described in connection with nanowire arrays, the surface protection schemes described herein may be applied to a variety of different device structures. Various planar catalytic surfaces may be modified to include nitrogen. For instance, a nitrogen layer (or other nitrogen-based layer) may be deposited or otherwise applied to a planar electrode surface. Methods of fabricating such devices to incorporate such nitrogen-based layers or other surface modifications are accordingly described.

Photoelectrochemical, photocatalytic, and other water splitting provided by the disclosed devices and systems may involve solar-to-hydrogen conversion. The disclosed devices and systems provide improvements in the efficiency of photoelectrochemical water splitting and/or other water splitting (e.g., photocatalytic water splitting). The disclosed devices and systems may include a double junction configuration for artificial photosynthesis and solar fuel conversion with significantly improved performance. For instance, the disclosed devices and systems may include InGaN nanowire arrays to provide a second junction. As described herein, such multi-band InGaN and other nanowire arrays are integrated directly on a nonplanar wafer for enhanced light absorption. A first junction of the device may be provided via one or more layers or other elements of the wafer.

Although described in connection with photoelectrochemical water splitting, the disclosed devices and systems may be used in other chemical reaction contexts and applications. For instance, the disclosed devices and systems may be useful in connection with various types of photocatalytic and/or other systems, and/or in connection with other reactions, including, for instance, nitrogen reduction to ammonia, CO₂ reduction to various fuels and other chemicals, and activation of C—H bonds for the production of various chemicals.

Although described herein in connection with electrodes having GaN-based nanowire arrays for water splitting, the disclosed devices and systems are not limited to GaN-based nanowire arrays. A wide variety of other types of nanostructures and other conductive projections may be used. In some cases, the electrodes of the disclosed systems do not include an array of projections, and are instead planar devices. Thus, the nature, construction, configuration, characteristics, shape, and other aspects of electrodes through which the water splitting is implemented may vary.

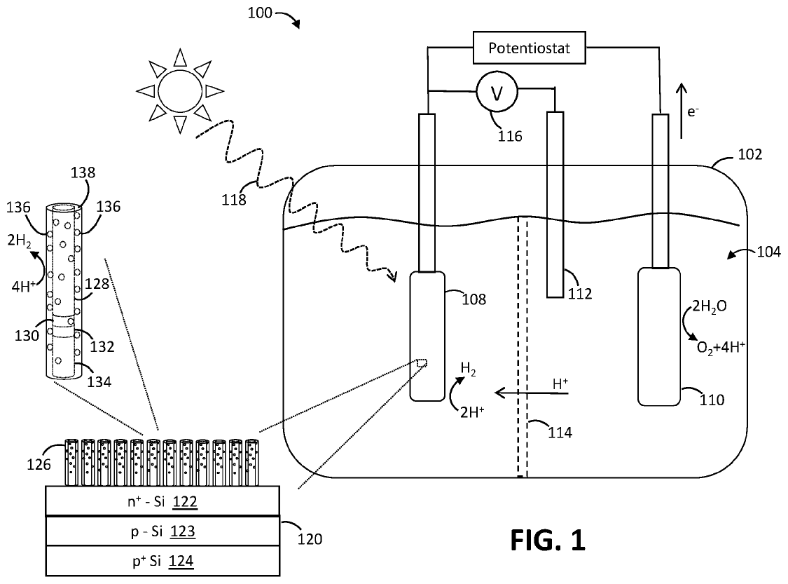

FIG. 1 depicts a system 100 for hydrogen evolution via water splitting. The system 100 may also be configured for other reactions. The system 100 may be configured as an electrochemical system. In this example, the electrochemical system 100 is a photoelectrochemical (PEC) system in which solar and/or other radiation is used to facilitate the hydrogen evolution and water splitting. The water splitting may be assisted or unassisted, as described herein. The manner in which the PEC system 100 is illuminated may vary. The wavelength and other characteristics of the radiation may vary accordingly.

The electrochemical system 100 includes one or more electrochemical cells 102. A single electrochemical cell 102 is shown for ease in illustration and description. The electrochemical cell 102 and other components of the electrochemical system 100 are depicted schematically in FIG. 1 also for ease in illustration. The cell 102 contains an electrolyte solution 104. In some cases, a CO₂ and/or other source is applied. In some cases, the electrolyte solution is saturated with CO₂. Potassium bicarbonate KHCO₃ may be used as an electrolyte. Additional or alternative electrolytes may be used, as described below. Further details regarding examples of the electrochemical system 100 are provided below.

In the example of FIG. 1, the electrochemical cell 102 has a three-electrode configuration. The electrochemical cell 102 includes a working electrode 108, a counter electrode 110, and a reference electrode 112, each of which is immersed in the electrolyte 104. The counter electrode 110 may be or include a metal wire, such as a platinum wire. The reference electrode 112 may be configured as a reversible hydrogen electrode (RHE). The positioning of the reference electrode 112 may vary from the example shown. For example, the reference electrode 112 may be adjacent to the counter electrode 110 in other cases. The configuration of the counter and reference electrodes 110, 112 may vary. For example, the counter electrode 110 may be configured as, or otherwise include, a photoanode at which water oxidation (4H₂O⇔2O₂+8e⁻+8H⁺) occurs. In some cases, the counter electrode 110 is configured as, or otherwise includes, an IrOx electrode. The configuration of the electrochemical cell may vary. For instance, in other cases, a two-electrode or other configuration may be used.

The hydrogen evolution occurs at the working electrode 108 as follows:

Hydrogen evolution: 2H⁺+2e⁻⇔H₂

To that end, electrons may flow from the counter electrode 110 through a circuit path external to the electrochemical cell 102 to reach the working electrode 108. The working and counter electrodes 108, 110 may thus be considered a cathode and an anode, respectively.

In the example of FIG. 1, the working and counter electrodes are separated from one another by a membrane 114, e.g., a proton-exchange membrane. The construction, composition, configuration and other characteristics of the membrane 114 may vary.

In some cases, no bias voltage is applied—e.g., in unassisted systems. In the example of FIG. 1, the circuit path includes a voltage source 116 of the electrochemical system 100. The voltage source 116 is configured to apply a bias voltage between the working and counter electrodes 108, 110. The bias voltage may be used to establish a ratio of CO₂ reduction to hydrogen (H₂) evolution at the working electrode, and/or another reaction ratio(s). The circuit path may include additional or alternative components. For example, the circuit path may include a potentiometer in some cases.

In this example, the working electrode 108 is configured as a photocathode. Light 118, such as solar radiation, may be incident upon the working electrode 108 as shown. The electrochemical cell 102 may thus be considered and configured as a photoelectrochemical cell. In such cases, illumination of the working electrode 108 may cause charge carriers to be generated in the working electrode 108. Electrons that reach the surface of the working electrode 108 may then be used in the hydrogen evolution. The photogenerated electrons may augment electrons provided via the current path. Alternatively or additionally, the electrons provided via the current path may recombine with the photogenerated holes at a backside or other contact. Further details regarding examples of photocathodes are provided below.

The working electrode 108 includes a substrate 120. The substrate 120 of the working electrode 108 may constitute a part of an architecture, a scaffolding, or other support structure, of the working electrode 108. The substrate 120 may be uniform or composite. For example, the substrate 120 may include any number of layers or other components. The substrate 120 thus may or may not be monolithic. The shape of the substrate 120 may also vary. For instance, the substrate 120 may or may not be planar or flat.

In the example of FIG. 1, the substrate 120 is doped and otherwise configured to present a junction. The substrate 120 of the working electrode 108 may thus be active (functional) in connection with the photogeneration of charge carriers. Alternatively or additionally, the substrate 120 is passive (e.g., structural). The substrate 120 may be configured and act as a support structure for a catalyst arrangement of the working electrode 108, as described below. Alternatively or additionally, the substrate 120 may be composed of, or otherwise include, a material suitable for the growth or other deposition of the catalyst arrangement of the working electrode 108.

In active or functional cases, the substrate 120 may include a light absorbing material. The light absorbing material is configured to generate charge carriers upon solar or other illumination. The light absorbing material has a bandgap such that incident light generates charge carriers (electron-hole pairs) within the substrate. Some or all of the substrate 120 may be configured for photogeneration of electron-hole pairs. To that end, the substrate 120 may include a semiconductor material. In some cases, the substrate 120 is composed of, or otherwise includes, silicon. For instance, the substrate 120 may be provided as a silicon wafer.

The silicon may be doped. In the example of FIG. 1, the substrate 120 includes a heavily n-type doped layer 122, a moderately or lightly p-type doped layer 123, and a heavily p-type doped layer 124. The arrangement of the layers 122-124 establishes a junction within the substrate 120. The doping arrangement may vary. For example, one or more components of the substrate 120 may be non-doped (intrinsic), or effectively non-doped. The substrate 120 may include alternative or additional layers, including, for instance, support or other structural layers. In other cases, the substrate 120 is not light absorbing.

The substrate 120 of the working electrode 108 establishes a surface at which a catalyst arrangement is provided. In some cases, catalyst support structures, or scaffolding, of the electrode 108 are provided as described below. As described below, the catalyst support structures may include an array of conductive projections extending outward from a surface of the substrate 120. In other cases, the catalyst arrangement does not include conductive projections. For instance, the catalyst arrangement may include one or more planar structures, such as one or more layers supported by the substrate 120.

In the example of FIG. 1, the working electrode 100 includes an array of nanostructures 126 (or other conductive projections) supported by the substrate 120. Each nanostructure 126 is configured to extract the charge carriers (e.g., electrons) from the substrate 120. The extraction brings the electrons to external sites along the nanostructures 126 for use in the hydrogen evolution. In some cases, each nanostructure 126 is configured as a nanowire. Each nanostructure 126 may have a semiconductor composition. In some cases, the semiconductor composition includes a semiconductor core. For instance, the core may be composed of, or otherwise includes, a Group III-V nitride semiconductor material, such as indium gallium nitride (InGaN). Additional or alternative semiconductor materials may be used, including, for instance, Gallium nitride (GaN) and/or other Group III-V nitride semiconductor materials.

The core of each nanowire or other nanostructure 126 may be or include a columnar, post-shaped, or other elongated structure that extends outward (e.g., upward) from the plane of the substrate 120. The semiconductor nanowires or other nanostructures 126 may be grown or formed as described in U.S. Pat. No. 8,563,395, the entire disclosure of which is hereby incorporated by reference. The nanostructures 126 may be referred to herein as nanowires with the understanding that the dimensions, size, shape, composition, and other characteristics of the nanostructures 126 or other conductive projections may vary.

The semiconductor composition of each nanostructure 126 may or may not be configured to facilitate the reaction(s) supported by the electrochemical system 100. The semiconductor composition may be configured for photo-generation of charge carriers, as described below. Alternatively or additionally, the semiconductor composition may be configured to act as a catalyst for the reaction(s). The semiconductor composition may provide other functions, including, for instance, protection of the substrate 120. As mentioned above, the semiconductor composition may include Gallium nitride and/or InGaN. Further details regarding a number of examples involving InGaN are provided below. Additional or alternative semiconductor materials may be used, including, for instance, indium nitride, aluminum nitride, boron nitride, aluminum oxide, silicon, and/or their alloys.

The semiconductor composition of each nanostructure 126 may be configured to provide surface passivation and/or other protection of the photoelectrode 108. For instance, in some cases, the semiconductor composition is terminated with nitrogen along surfaces of the nanostructure 126. The nitrogen termination or other nitrogen-based aspect of the nanostructures 126 may protect the nanostructures 126 and/or other components of the electrode 108 (e.g., the substrate 120) during operation from, e.g., corrosion. Alternative or additional nitrogen-based protection schemes may be used in other cases. For instance, a layer including nitrogen may be deposited or otherwise disposed along the surface of each nanostructure 126 and/or other element of the electrode 108.

The nanostructures 126 may facilitate the hydrogen evolution and/or another chemical reaction in one or more ways. For instance, each nanostructure 126 may be configured to extract the charge carriers (e.g., electrons) generated in the substrate 120. The extraction brings the electrons to external sites along the nanostructures 126 for use in the hydrogen evolution and/or other chemical reaction. The composition of the nanostructures 122 may also form an interface well-suited for hydrogen evolution and/or another chemical reaction, as explained below.

Each nanostructure 126 may be or include a columnar, post-shaped, or other elongated structure that extends outward (e.g., upward) from the plane of the substrate 120. The dimensions, size, shape, composition, and other characteristics of the nanostructures 126 may vary. For instance, each nanostructure 126 may or may not be elongated like a nanowire. Thus, other types of nanostructures from the substrate 120, such as various shaped nanocrystals, may be used.

In the example of FIG. 1, the nanostructures 126 are configured to generate electron-hole pairs upon illumination. For instance, the nanostructures 122 may be configured to absorb light at frequencies different than other light absorbing components of the electrode 108. For example, one light absorbing component, such as the substrate 120, may be configured for absorption in the visible or infrared wavelength ranges, while another component may be configured to absorb light at ultraviolet wavelengths. In other cases, the nanostructures 126 are the only light absorbing component of the electrode 108. In still other cases, the substrate 120 is the only light absorbing component of the electrode 108.

Each nanowire 126 may include a layered or segmented arrangement of semiconductor materials. For instance, in Group III-nitride examples, the layers or segments of the arrangement may have differing Group III (e.g., indium and gallium) compositions. One or more layers or segments in the arrangement may be configured for absorption of a respective range of wavelengths. In the example of FIG. 1, each nanowire 126 includes a segment 128 having a compound semiconductor composition (e.g., InGaN) configured for photogeneration of charge carriers. Other layers or segments may be directed to establishing a tunnel junction. In the example of FIG. 1, each nanowire 126 includes segments 130, 132 having a compound semiconductor composition (e.g., InGaN) configured to establish a tunnel junction. Each nanowire 126 may also include additional or alternative segments, including, for instance, a segment 134 between the tunnel junction and the substrate 120. Further details regarding a number of examples of segmented arrangements are provided below.

In other cases, the layered arrangement of semiconductor materials is also used to establish a multi-band structure, such as a quadruple band structure. Each layer or segment of the arrangement may have a different semiconductor composition to establish a different bandgap. The different bandgaps may be useful in connection with absorbing light of differing wavelengths.

The layered arrangement of the nanowires 126 may vary from the examples described herein. For example, further details regarding the formation and configuration of multi-band structures, including, for instance, triple-band structures, are provided in U.S. Pat. No. 9,112,085 (“High efficiency broadband semiconductor nanowire devices”) and U.S. Pat. No. 9,240,516 (“High efficiency broadband semiconductor nanowire devices”), the entire disclosures of which are incorporated by reference.

The semiconductor composition of each nanowire 126 may be configured to improve the efficiency of the water splitting in additional ways. For instance, in some cases, the semiconductor composition of each nanowire 126 may include doping to promote charge carrier separation and extraction, as well as facilitate the establishment of a photochemical diode. For example, a dopant concentration of the semiconductor composition may vary laterally.

In examples involving III-nitride compositions, the dopant may be or include magnesium. Further details regarding the manner in which magnesium doping promotes charge carrier separation and extraction are set forth in U.S. Pat. No. 10,576,447 (“Methods and systems relating to photochemical water splitting”), the entire disclosure of which is incorporated by reference. Additional or alternative dopant materials may be used, including, for instance, silicon, carbon, and beryllium, depending on the semiconductor light absorber of choice.

The semiconductor device may further include catalyst nanoparticles 136 disposed over the array of nanowires 126. The nanoparticles 136 are distributed across or along the outer surface (e.g., sidewalls) of each nanowire 126. The nanoparticles 136 are configured to facilitate or promote the proton reduction reaction. In some cases, each nanoparticle 136 includes a metal, such as platinum. Other metals or materials may be used, including alloys, oxides, and/or other metal or metallic combinations. Further details regarding the formation, configuration, functionality, and other characteristics of nanoparticles 136 in conjunction with a nanowire array are set forth in one or more of the above-referenced U.S. patents. Further details regarding the distribution of the nanoparticles 136 are provided below in connection with a number of examples.

The nanoparticles 136 may be sized in a manner to facilitate the water splitting. The size of the nanoparticles 136 may be useful in catalyzing the reaction, as described herein. In some cases, each nanoparticle 136 has a size (e.g., a diameter) falling in a range from about 2 nm to about 3 nm, but other sizes may be used in other cases. The size of the nanoparticles 136 may promote the water splitting in additional or alternative ways. For instance, the nanoparticles 136 may also be sized to avoid inhibiting the illumination of the nanowires 126 and/or the substrate 120.

In some cases, the electrode 108 may include nanoparticles with a size larger than the above-referenced range. In such cases, the electrode 108 nonetheless includes a plurality of nanoparticles having a size that falls within a desired range as described herein.

The distribution of the nanoparticles 136 may be uniform or non-uniform. The nanoparticles may thus be distributed randomly across each nanowire 126. The schematic arrangement of FIG. 1 is shown for ease in illustration.

The electrode 108 also includes an oxide layer 138 covering the catalyst nanoparticles 136 and each nanostructure 126 of the array of nanostructures 126. The oxide layer 138 acts as a passivation and/or other protection layer. For example, the oxide layer 138 may be configured to protect the nanoparticles 136 and/or passivate the surface of the nanostructures 126. In some cases, the oxide layer 138 is composed of, or otherwise includes, aluminum oxide. Alternative or additional oxide materials may be used, including, for instance, titanium oxide, gallium (and/or aluminum) oxide, and/or gallium (and/or aluminum) oxide nitride (or oxynitride). The oxide layer 138 may have a thickness on the order of a size of each catalyst nanoparticle 136. For instance, the thickness of the oxide layer 138 may fall within a range of about 1 nm to about 2 nm, but other thicknesses may be used. In these and other cases, the oxide layer 138 conformally covers the catalyst nanoparticles 136 and the array of nanostructures 126. For instance, the oxide layer 138 may conformally cover the sidewalls and other surfaces of the nanostructures 126, as shown in FIG. 1. The conformal coverage of the nanostructure surfaces and nanoparticles is depicted schematically for ease in illustration.

The oxide layer 138 may conformally cover other structures or components of the electrode 108. For instance, in planar examples, the oxide layer 138 may be or otherwise include a planar layer deposited or otherwise disposed across one or more planar surfaces of the electrode. The planar surface(s) may or may not include a distribution of catalyst nanoparticles.

The thin nature of the oxide layer 138 allows the protection function to be provided without adversely affecting the transfer of charge carriers and other catalysis of the hydrogen evolution and/or other reaction occurring at the electrode 108. Further details regarding the functionality and other characteristics of the oxide layer 138 are provided below in connection with a number of examples.

The nanowires 126 and the nanoparticles 136 are not shown to scale in the schematic depiction of FIG. 1. The shape of the nanowires 126 and the nanoparticles may also vary from the example shown. Further details regarding the nanowire-nanoparticle co-catalyst arrangement, including the fabrication thereof, are provided below.

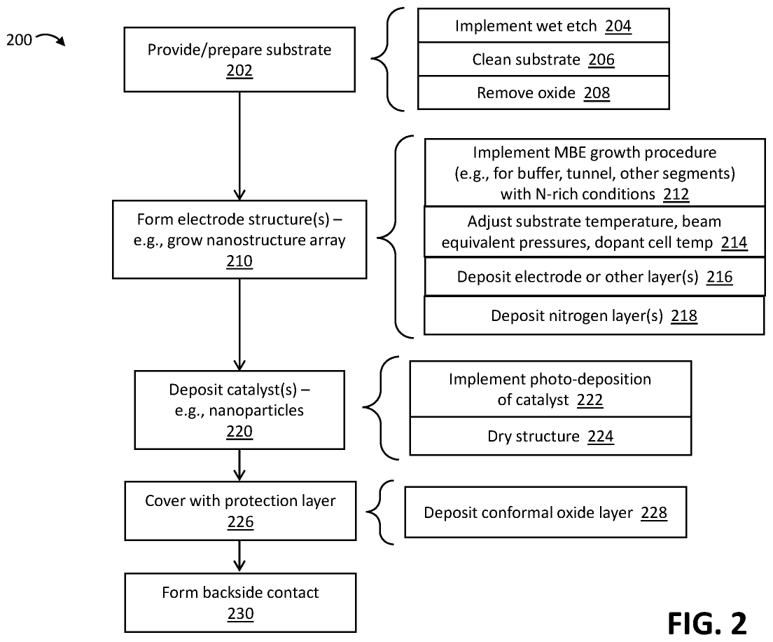

The nanoparticle-nanowire catalyst arrangement may be fabricated on a substrate (e.g., a silicon substrate) via nanostructure-engineering. In one example, molecular beam epitaxial (MBE) growth of the nanowires is followed by photo-deposition of the nanoparticles. The photo-deposition of the nanoparticles may be configured to selectively deposit the nanoparticles on the respective sides of the nanowire. Further details regarding example fabrication procedures are provided below, e.g., in connection with FIG. 2.

The nanowires 126 may facilitate the water splitting in alternative or additional ways. For instance, each nanowire 126 may be configured to extract charge carriers (e.g., electrons) generated in the substrate (e.g., as a result of light absorbed by the substrate 120). The extraction brings the charge carriers to external sites along the nanowires 126 for use in the water splitting or other reactions. For instance, the nanowires 126 may thus form an interface well-suited for evolution of hydrogen, the reduction of CO₂, and/or other reactions.

FIG. 2 depicts a method 200 of fabricating a photoelectrode or other semiconductor device for photocatalytic water splitting, PEC water splitting, or other photocatalytic reactions, in accordance with one example. The method 200 may be used to manufacture any of the photoelectrodes or other devices described herein or another device. The method 200 may include additional, fewer, or alternative acts. For instance, the method 200 may or may not include one or more acts directed to forming a backside contact of the device (act 230).

The method 200 may begin with an act 202 in which a substrate is prepared or otherwise provided. The substrate may be or be formed from a silicon wafer. In one example, a 2-inch Si wafer was used, but other (e.g., larger) size wafers may be used. Other semiconductors and substrates may be used.

The substrate may have a planar or nonplanar surface. In some cases, the act 202 includes an act 204 in which a wet or other etch procedure is implemented to define the surface. For example, the etch procedure may be or include a crystallographic etch procedure. In silicon substrate examples, the crystallographic etch procedure may be a KOH etch procedure. In such cases, if the substrate has a <100> orientation, the wet etch procedure establishes that the surface includes a pyramidal textured surface with faces oriented along <111> planes.

The act 202 may include fewer, additional, or alternative acts. For instance, in the example of FIG. 1, the act 202 includes an act 206 in which the substrate is cleaned, and an act 208 in which oxide is removed.

In one example, a prime-grade polished silicon wafer is etched in 80° C. KOH solution (e.g., 1.8% KOH in weight with 20% isopropanol in volume) for 30 minutes to form the micro-textured surface with Si pyramids. After being neutralized in concentrated hydrochloric acid, the substrate surface is cleaned by acetone and/or methanol, and native oxide is removed by 10% hydrofluoric acid.

The act 202 may include still further acts. For instance, the act 202 may include one or more doping procedures to form doped regions or layers, and thereby establish a junction, as described herein. Alternatively, the substrate is provided at the outset with a desired dopant concentration profile.

The method 200 includes an act 210 in which electrode or other device structure(s) is grown or otherwise formed on the substrate. In some cases, a nanowire or other nanostructure array is grown or otherwise formed on the substrate. Each nanowire is formed on the surface of the substrate such that each nanostructure extends outward from the surface of the substrate. Each nanostructure may have a semiconductor composition, as described herein. In one example, Mg-doped InGaN nanowires were grown by plasma-assisted molecular beam epitaxy (MBE) under N-rich conditions.

The nanostructure growth may be achieved in an act 212 in which a molecular beam epitaxy (MBE) procedure is implemented. The substrate may be rotated during the MBE procedure such that each nanostructure is shaped as a cylindrically shaped nanostructure. Each nanostructure may thus have a circular cross-sectional shape, as opposed to a plate-shaped or sheet-shaped nanostructure.

The MBE procedure may be implemented under nitrogen-rich conditions. The nitrogen-rich conditions may lead to nitrogen-terminated sidewalls and other surfaces, as described herein.

In some cases, the MBE procedure may be modified to fabricate the arrangement of layers or segments of each nanowire. Various parameters may be adjusted to achieve the different composition levels of the segments. For instance, the substrate temperature may be adjusted in an act 214. Beam equivalent pressures may alternatively or additionally be adjusted. In some cases, a dopant cell temperature is adjusted to control the doping (e.g., Mg doping) of the nanowires.

In other cases (e.g., non-nanostructure cases), the act 210 may include forming other types of electrode or other device structures, such as one or more layers. The layer(s) may be configured to catalyze, participate in, or otherwise enable or facilitate the reaction. The layer(s) may accordingly be referred to as a reaction layer. For instance, the reaction layer(s) may be deposited on the substrate in an act 216. The layer(s) may establish a surface configured to catalyze or otherwise facilitate the water splitting and/or other reaction. The electrode layer(s) may be formed in alternative or additional ways, including, for instance, non-selective growth procedures.

One or more nitrogen-containing layers may be deposited or otherwise formed in an act 218 to protect the reaction layer(s). For example, the act 218 may include implementing a reaction to form the nitrogen-containing layer(s) spontaneously. The layer(s) may be composed of, or otherwise include, a nitride or an oxynitride. In some cases, the layer(s) may be formed on an electrode or other device structure that is planar (e.g., a structure that includes a number of planar layers or other planar components). The configuration of the planar structures may vary. Examples of planar structures are described in Cheng, et al., “Monolithic Photoelectrochemical Device for Direct Water Splitting with 19% Efficiency,” ACS Energ. Lett., 3, (8), 1795-1800 (2018), Young, et al., “Direct solar-to-hydrogen conversion via inverted metamorphic multi-junction semiconductor architectures,” Nat. Energ., 2, 17028 (2017), Khaselev et al., “A monolithic photovoltaic-photoelectrochemical device for hydrogen production via water splitting,” Sci., 280, (5362), 425-427 (1998), and Verlage et al., “A monolithically integrated, intrinsically safe, 10% efficient, solar-driven water-splitting system based on active, stable earth-abundant electrocatalysts in conjunction with tandem III-V light absorbers protected by amorphous TiO2 films,” Energ. Environ. Sci., 8, (11), 3166-3172 (2015), the entire disclosures of which are hereby incorporated by reference.

A wide variety of planar and other structures may be protected by the nitrogen-containing layer(s). For instance, the nitrogen-containing layer(s) may be deposited or otherwise formed on various surfaces not involving a c-plane surface or a nonpolar plane or surface.

In some cases, the act 218 may be integrated with, or implemented in conjunction with, the act 216, as described herein in conjunction with examples involving GaN or other nanostructures. In other cases involving GaN nanostructures, the acts 216 and 218 may be implemented separately.

In the example of FIG. 2, the method 200 further includes an act 220 in which catalyst nanoparticles are deposited across the array of nanowires. The deposition of the nanoparticles may be achieved via implementation of a photo-deposition procedure in an act 222. The nanoparticles may be composed of, or otherwise include, a metal, such as platinum, or other metallic material. A drying act 224 may then be implemented. Further details regarding the photo-deposition procedures are set forth in one or more of the above-referenced U.S. patents.

In one example, the catalyst nanoparticles were deposited using a photo-deposition procedure in which an InGaN nanowire device was put in a glass chamber with a quartz lid. The chamber was pumped down and then illuminated using a 300 W Xenon lamp for 20 minutes to deposit catalyst nanoparticles on the InGaN nanowires.

The method 200 may then include an act 226 in which the nanostructures are covered with a passivation or protection layer. The protection layer may be or otherwise include a conformal oxide layer deposited in an act 228. The oxide layer may be composed of, or otherwise include, aluminum oxide. The deposition of the act 228 may include implementation of an atomic layer deposition (ALD) procedure, and/or be otherwise configured to control the thickness of the oxide layer as described herein. Further details regarding examples are provided below.

The method 200 may include one or more additional acts directed to forming the photocatalytic structures of the device. For instance, in some cases, the method 200 includes an act 230 in which a backside contact is formed. Still other acts may include a procedure in which the photocatalytic structures of the device are annealed. The parameters of the anneal process may vary.

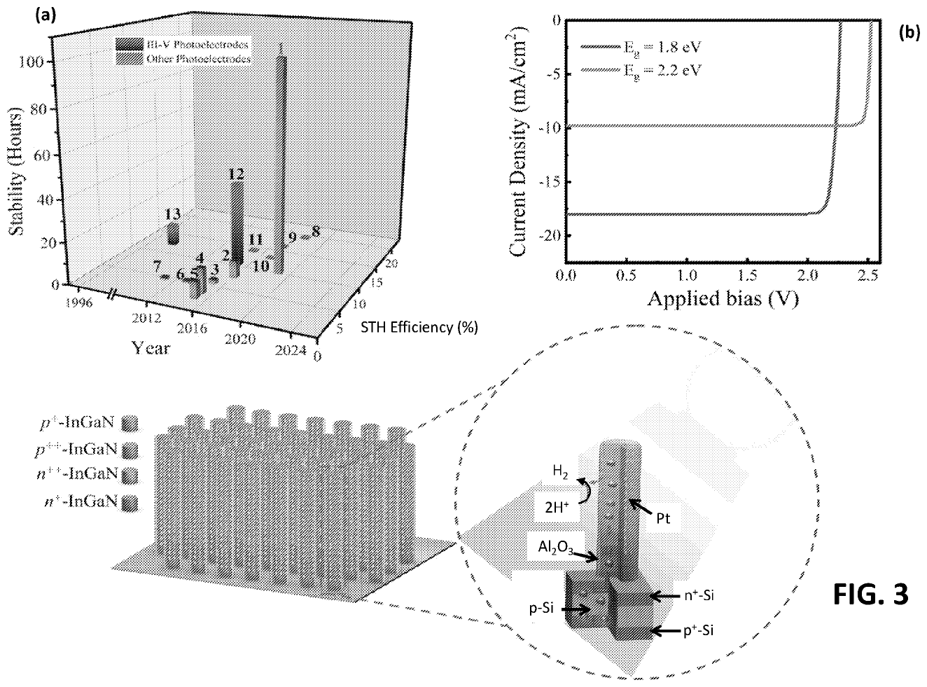

Details regarding examples of the above-described devices, systems, and methods are now provided in connection with FIGS. 3-8, which address examples of InGaN—Si double junction photocathodes for unassisted solar water splitting. The disclosed photocathodes simultaneously achieve efficient and stable operation for sustainable and economical solar water splitting systems. The disclosed photocathodes are configured as a monolithically integrated InGaN/Si double-junction photocathode that can enable relatively efficient and stable unassisted solar water splitting. The disclosed photocathodes include a p-type InGaN top junction, which is monolithically integrated on a bottom Si p-n junction through a dislocation-free n++/p++ InGaN nanowire tunnel junction. With the incorporation of Pt catalysts and a thin Al₂O₃ surface passivation layer, a solar-to-hydrogen efficiency of about 10.3% and stable operation of 100 h was measured in 0.5 M H₂SO₄ in two-electrode configuration for unbiased photoelectrochemical water splitting. Such an efficient and stable water splitting device is achieved using the two most produced semiconductors, e.g., Si and Ga(In)N, promising large-scale implementation of efficient, stable, and low-cost solar hydrogen production systems.

Solar hydrogen (H₂) fuel is one of the best sustainable and clean alternatives to address the increasing global energy demand by using the two most abundant natural resources on earth, i.e., water and sunlight. Photoelectrochemical (PEC) water splitting is one of the most promising approaches for solar hydrogen production. For this approach to be competitive, it is pertinent to achieve solar-to-hydrogen (STH) efficiency>10%, lifetime stability>10 years and low H₂ production costs. PEC devices using a tandem configuration, with a top light absorber bandgap of about 1.8 eV and bottom light absorber bandgap of about 1.1 eV, have the potential to reach a maximum theoretical STH efficiency of about 30%. Apart from the energy bandgap, a tandem device may have a functional tunnel junction (TJ), which is optically transparent and electrically conducting and possess a low level of structural defects and dislocations. Significant progress has been made in unassisted PEC water splitting for solar-hydrogen production in the past two decades. The state-of-the-art STH efficiency and stability reported for some of these photoelectrodes is summarized in Part (a) of FIG. 3. Although STH efficiency values up to 19% have been reported, they suffer from several critical issues, including: i) poor stability due to their inherent spontaneous photo-corrosion and oxidation in acidic or alkaline electrolytes, and ii) high costs associated with the large area III-V substrates. Significant efforts have been devoted to improving the stability of III-V water splitting devices, including the incorporation of a TiO₂ surface protection layer and the bifacial electrode design with thick metal layers for GaAs photoelectrodes. These approaches, however, have had limited success, and often lead to significantly reduced STH efficiency. Illustrated in Part (a) of FIG. 3, even with various surface protection schemes, the stability of III-V water splitting devices is still low (<40 h) when measured in practical two-electrode conditions. On the other hand, as seen in Part (a) of FIG. 3, tandem photoelectrodes based on non-III-V materials, e.g., Si and metal oxides such as BiVO₄ and Fe₂O₃, are often plagued by very low STH efficiencies, in addition to limited stability. There exists, therefore, a challenge to fabricate semiconductor photoelectrodes that are intrinsically stable, can be manufactured at low cost, and have tunable energy bandgap for efficient tandem water splitting devices.

In this context, III-nitride semiconductors, i.e., Ga(In)N, have been used for next generation semiconductor photoelectrodes. They exhibit tunable direct bandgap from 0.65 eV (InN) to 3.4 eV (GaN), and have large carrier mobility and high light absorption coefficient. As such, III-nitrides have been intensively studied for PEC water splitting, as well as other artificial photosynthesis devices. The surfaces of III-nitride nanostructures can be engineered to be N-rich, not only for their top c-plane, but also for their nonpolar sidewalls, which can protect against photocorrosion and oxidation, and are stable in various electrolytes. Moreover, such N-terminated III-nitride nanostructures can be grown directly on Si wafer without the formation of extensive dislocations, providing distinct opportunities to realize Si-based double-junction PEC water splitting devices with a nearly ideal energy bandgap configuration, i.e., about 1.1 eV and 1.8 eV for the bottom Si and top In_{0.46}Ga_{0.54}N junction, respectively. Illustrated in Part (b) of FIG. 3 is the simulated J-V characteristics for such a double-junction device, which can exhibit a maximum photocurrent density of about 18 mA/cm² and photovoltage of about 2.2 V under AM1.5G one sun illumination. To date, however, such an InGaN/Si double-junction PEC device has not been realized for unassisted PEC water splitting, partly limited by the lack of a defect-free tunnel junction that can integrate the top InGaN light absorber with the bottom Si p-n junction. In addition, the performance of such nanostructured PEC water slitting devices suffers from surface recombination of photo-generated charge carriers and the poor adhesion of photocatalyst nanoparticles on semiconductor surfaces.

As disclosed herein, these challenges are addressed, for the first time, with an InGaN/Si double-junction device for unassisted PEC solar water splitting, which is achieved by utilizing a defect-free n⁺⁺-InGaN/p⁺⁺-InGaN nanowire tunnel junction to monolithically integrate the top N-terminated p⁺-InGaN light absorber with the underlying Si p-n junction. Moreover, an ultrathin Al₂O₃ surface passivation layer is uniformly deposited on InGaN nanowire surfaces by atomic layer deposition (ALD), which significantly reduces surface recombination of photo-generated charge carriers and further helps stabilize Pt catalyst nanoparticles. A tandem PEC device consisting of a top p⁺-InGaN cell with an energy bandgap of about 2.2 eV shows Vₒₙ of about 0.7 V vs. IrOx and photocurrent density of about 8.4 mA/cm² at 0 V vs. IrOx under AM 1.5 G one-sun illumination in 0.5 M H₂SO₄, with STH of about 10.3%. Chronoamperometry analysis for the photocathode shows stable operation for 100 h without any performance degradation for unassisted water splitting. Further impedance studies reveal the charge transfer mechanism in the double-junction device. Given that Si and Ga(In)N, the two most produced semiconductors, can be manufactured at large scale with relatively low cost, the disclosed photoelectrode provides a new approach for developing high efficiency and high stability PEC water splitting for solar H₂ production.

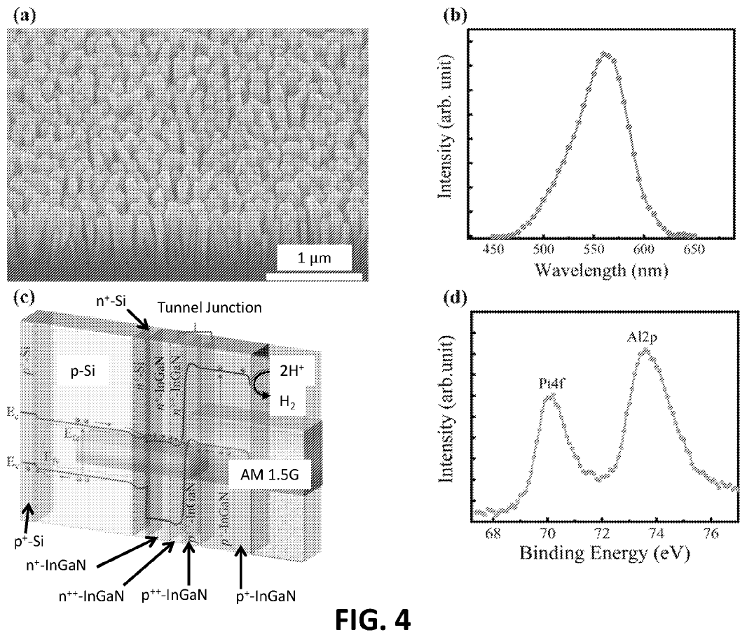

As shown in Part (c) of FIG. 3, the double junction photocathode includes a p⁺-InGaN top light absorber, p⁺⁺-InGaN/n⁺⁺-InGaN tunnel junction, and n⁺-p Si bottom light absorber. The n⁺-p Si wafers may be prepared using thermal diffusion. The scanning electron microscope (SEM) image, illustrated in Part (a) of FIG. 4, shows the nanowires are vertically aligned on n⁺-p Si wafer with diameters of about 80 nm and lengths of about 600-700 nm, although the sizes may vary. The growth of InGaN nanowires on Si show that PEC devices with the incorporation of an InGaN top cell with an average indium composition of about 32% and an energy bandgap of about 2.2 eV provide useful PEC performance. The photoluminescence (PL) emission spectrum (see Part (b) of FIG. 4) of the best PEC performing region, shows a strong peak emission at about 560 nm, corresponding to an energy bandgap 2.2 eV. The broad spectral linewidth also indicates significant indium compositional fluctuations in from nanowire to nanowire, or within the same nanowires. Given the conduction band edge of In_{0.32}Ga_{0.68}N (about −0.5 V vs. RHE at pH=0), photoexcited electrons from p⁺-InGaN may reduce protons without any external bias. Additionally, the conduction band edges of GaN and Si are near-perfectly aligned, which enables efficient transfer of photoexcited electrons from the underlying Si light absorber to the top p⁺-InGaN. This unique property, together with the large surface area and light scattering and trapping of nanowires, is useful to achieve high efficiency InGaN/Si double-junction photoelectrodes by significantly improving the charge carrier extraction (see Part (c) of FIG. 3) as well as light absorption. The photo-generated electrons from n⁺-p Si wafer are extracted by n⁺-InGaN nanowire arrays as shown in the inset of Part (c) of FIG. 3. Also shown in Part (c) of FIG. 4, the downward band bending of p⁺-InGaN can promote the extraction of photo-generated electrons to the electrolyte. Additionally, due to the large valence band offset between n⁺-InGaN and Si, the bottom n⁺-InGaN acts as an active hole blocking layer for n⁺-p Si to effectively suppress surface recombination. Photo-generated electrons from the bottom Si cell recombine with the photo-generated holes from the top p⁺-InGaN layer in the tunnel junction (e.g., FIGS. 3(c) and 4(c)). Instead of forming the tunnel junction directly on Si, the tunnel junction is incorporated on top of the bottom n⁺-InGaN segment. This is because tunnel junction incorporated in a nanowire segment has significantly less defects and dislocations compared to direct integration on Si substrate, due to the lattice mismatch between InGaN and Si. Defect-free Ga(In)N nanowires can significantly enhance the performance of single junction Si photocathode. To elucidate the role of the tunnel junction and top p+-InGaN on the double junction performance, n⁺-InGaN nanowires/Si single junction photocathode are used as a control sample.

The disclosed p⁺-InGaN/TJ/n⁺-p Si photocathode undergoes two-step surface modification as shown in Part (b) of FIG. 3. In the first step, Pt nanoparticles are deposited on p⁺-InGaN/TJ/n⁺-p Si using photo-deposition (examples of which are described below). To further reduce the charge transfer losses due to the surface recombination, it is useful to deposit a passivation layer. In the second step of surface modification, as shown in the inset of Part (c) of FIG. 3, the Pt nanoparticles/p⁺-InGaN/TJ/n⁺-p Si photocathode is covered by a thin layer of Al₂O₃ (examples of which are described below). Even though Al₂O₃ is amphoteric, the Al₂O₃ layer is stable in PEC reactions. The Al₂O₃ layer, which is a conductive transparent oxide layer, acts as a passivation layer for the photoelectrode. This passivation layer not only protects the photoelectrode against oxidation in the electrolyte, but also enhances the overall reaction kinetics by reducing surface recombination. Metal-organic chemical vapor deposition (MOCVD) grown Ga-terminated n-GaN epilayers with an Al₂O₃ protection layer (about 1-2 nm) achieve enhanced stability and reduced overpotential under water oxidation conditions. The effect of a thin Al₂O₃ passivation layer in reducing charge carrier transfer resistance and providing better stability is discussed below. The X-ray Photoelectron Spectroscopy (XPS) of samples after surface modifications are shown in Part (d) of FIG. 4. The Pt4f and Al2p have peak positions at 70.2 eV and 73.9 eV, respectively, which correspond to metallic Pt peak and Al₂O₃ peak.

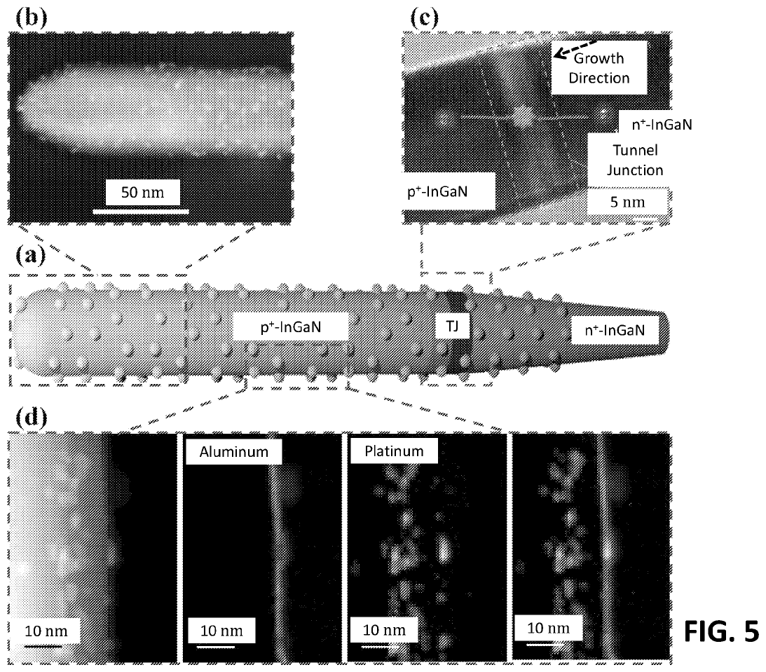

Structural properties of the samples were further characterized using SEM and scanning transmission electron microscopy (STEM). Part (a) of FIG. 5 shows the schematic representation of a single p⁺-InGaN/TJ nanowire with Pt nanoparticles and Al₂O₃ passivation layer. The STEM high-angle annular dark field (HAADF) image in Part (b) of FIG. 5 shows that the top segment of p⁺-InGaN nanowire (box region in Part (a) of FIG. 5) has a diameter of about 80 nm with Pt nanoparticles (size of about 2-3 nm) coverage. The tunnel junction region of the nanowire is identified in Part (c) of FIG. 5. The p⁺⁺-InGaN/n⁺⁺-InGaN tunnel junction is useful to enable recombination of photogenerated charge carriers between the top p⁺-InGaN subcell and bottom Si subcell without significant ohmic loss, thereby producing sufficient open-circuit potential (discussed below) for unassisted water splitting. Furthermore, in Part (d) of FIG. 5, the nanowire sidewall is analyzed using electron energy loss spectroscopy (EELS) mapping. The STEM-HAADF image in Part (d) of FIG. 5 shows Pt nanoparticles coverage on the sidewall of the nanowire and on the top/bottom surfaces as the images show a 3D projection of the structure onto a 2D image. The EELS elemental mappings in Part (d) of FIG. 5 clearly show the presence of Al and Pt on the sidewall of the nanowire. The thickness of the Al₂O₃ layer on the nanowire from Part (d) of FIG. 5 is found to be about 1-2 nm, which is in good agreement with the thickness calibration by ALD. In addition, the energy-dispersive X-ray spectroscopy (EDX) mapping further shows the presence of Al₂O₃ on the nanowires. These results confirm the conformal nature and coverage of the Al₂O₃ layer over the nanowires and Pt nanoparticles.

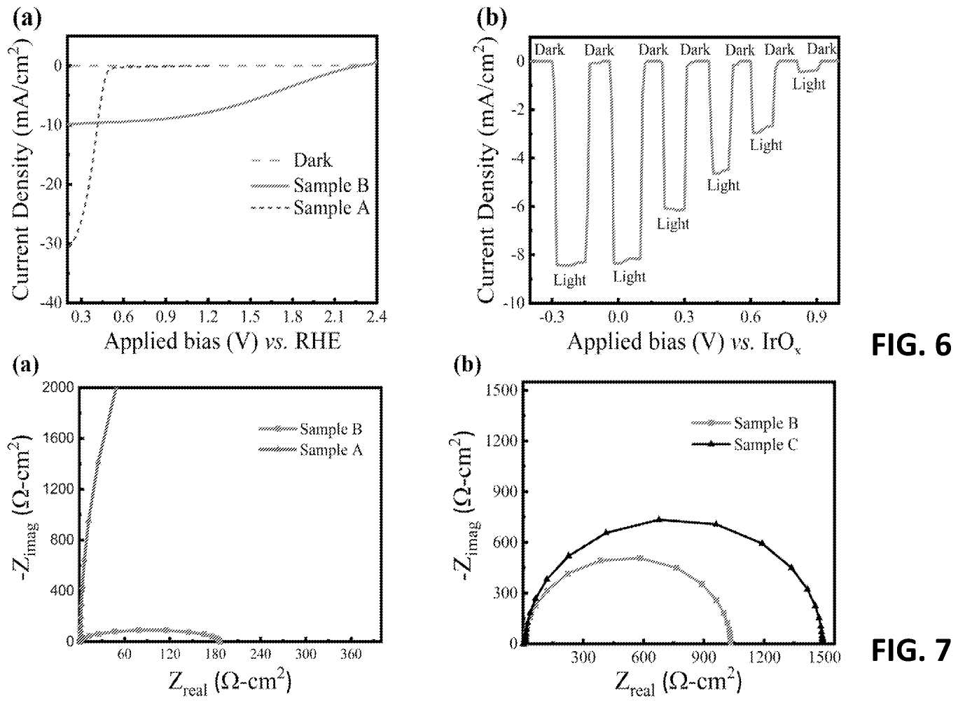

Three different samples were studied to elucidate the PEC properties of the InGaN/Si double-junction photocathode. Sample A, n⁺-InGaN/Si, is a platinized single junction photocathode without the tunnel junction or the top p⁺-InGaN segment, which serves as a control sample. It has similar working principle as the previously reported GaN/Si single-junction photocathodes. Samples B and C are the double junction samples with and without Al₂O₃ passivation layer, respectively. The PEC performance comparisons between these three samples clearly show the effects of the tunnel junction, the top p⁺-InGaN subcell, and the Al₂O₃ passivation layer in reducing kinetic losses, enhancing open-circuit potential, and improving device stability. The PEC experimental conditions are described below. Part (a) of FIG. 6 shows the three-electrode linear scan voltammogram (LSV) comparison between Sample B (red curve) and Sample A (blue curve) under AM 1.5 G one-sun illumination and dark condition (green curve). Sample A (single junction Si) has Vₒₙ of about 0.5 V vs. RHE, whereas Sample B (double-junction InGaN/TJ/Si) has Vₒₙ of about 2.3 V vs. RHE. Compared to Part (b) of FIG. 3, Vₒₙ of Sample B is about 100 mV higher than theoretically calculated ideal In_{0.46}Ga_{0.54}N/Si double junction and about 300 mV lower than theoretically calculated ideal In_{0.32}Ga_{0.68}N/Si double junction. As shown in FIG. 1(b), the Vₒₙ difference of about 400 mV between ideal In_{0.46}Ga_{0.54}N/Si and double-junction devices are directly correlated to the difference between bandgap of the top junctions. However, the variations in the Vₒₙ and fill factors between the theoretical simulations (Part (b) of FIG. 3) and experimental results (Part (a) of FIG. 6) is because, in the simulation, ideal ohmic contacts are assumed, without any voltage loss, for tunnel junction interface, backside metal contacts, and semiconductor/liquid interface. Open circuit potential (OCP) measurements vs. RHE under chopped light illumination for Sample B exhibit a dark potential of about 0.3 V and light potential of about 2.3 V (same as Vₒₙ), with a change in OCP of about 2 V. Assuming a relatively small HER overpotential, the Vₒₙ will be close to flat-band potential (V_{fb}) derived from the Mott-Schottky measurements. As shown in Part (a) of FIG. 6, the maximum saturation photocurrent density for Sample B is about 9 mA/cm² at 0.3 V vs. RHE. Compared to Sample A, the photocurrent density for Sample B is lower at 0.3 V vs. RHE. This is because the device is limited by the top p⁺-InGaN segment (with a band gap of about 2.43 eV), which can give a theoretical maximum of up to 10 mA/cm², whereas the single-junction photocathode (Sample A, Si being the primary light absorber) has a theoretical maximum photocurrent density of about 44 mA/cm². The applied bias photon-to-current efficiency (ABPE) of this photocathode is about 9.6% at 1.3 V vs. RHE. The ABPE is one of the highest for Si-based photocathodes.

Part (b) of FIG. 6 shows the chopped two-electrode LSV of Sample B under AM 1.5 G one sun illumination and dark conditions. The PEC performance optimization of the photocathode in terms of Al₂O₃ deposition conditions is discussed below. OCP and Mott-Schottky measurements clearly show that Sample B can perform unassisted water splitting with sufficient photovoltage to overcome the water redox potentials including the HER overpotential. As shown in Part (b) of FIG. 6, the maximum photocurrent density for Sample B, at 0 V vs. IrOx, is about 8.4 mA/cm² with Vₒₙ of about 0.7 V vs. IrOx under AM 1.5 G one-sun illumination in 0.5 M H₂SO₄. Significant indium compositional variations in the nanowires may also impact Vₒₙ. The photocurrent density of Sample B, with optimized Al₂O₃ thin film, is higher than Sample C (about 5.5 mA/cm2) at 0 V vs. IrOx. It is clear from the LSV data for Sample C that there is considerable surface recombination within the structure which gives a poor fill-factor and thereby reduces the saturated photocurrent density of this device. The PL intensity of InGaN/Si sample is reduced after depositing Pt nanoparticles, which can be explained by the enhanced charge carrier separation and extraction due to the formation of Schottky barrier at the interface of InGaN and Pt. In contrast, the PL intensity of InGaN/Si sample after deposition of a thin Al₂O₃ layer is increased due to the reduction in surface recombination. The effect of Al₂O₃ on the double junction in terms of improving charge transfer characteristics is further discussed below. The STH (at 0 V vs. IrOx), calculated for Sample B is 10.3% under AM 1.5 G one-sun illumination. As shown in Part (a) of FIG. 3, this is the highest known STH for Si and non-III-V based photocathodes. From theoretical simulations (see Part (b) of FIG. 3), the photocurrent density and STH of an ideal InGaN/Si double-junction photocathode, with energy bandgaps of about 2.2 eV and 1.1 eV, is about 10 mA/cm² and 12.3%, respectively, which can be further improved by optimizing the energy bandgap of InGaN. Experimentally, the broad indium compositional variations in nanowire structures, i.e., a significant portion of the nanowires or nanowire regions showing energy bandgap less than 2.2 eV, may also lead to enhanced light absorption (and therefore higher photocurrent) compared to a single bandgap material. There is significant room for improving the light absorption and charge transfer kinetics of InGaN/Si photocathode and surface passivation to achieve higher STH. Apart from the two-electrode LSV measurements, it is useful to consider the spectral response of the double-junction photocathode. A tandem photoelectrode involves customized incident photon-to-current conversion efficiency (IPCE) analysis to each subcell, as per the protocols, to determine the maximum STH under two-electrode configuration. It is to be noted that IPCE measurement of a tandem photoelectrode is significantly more challenging and complex when compared to single junction devices, due to the two-terminal configuration in which the subcells cannot be individually measured. The challenges of performing IPCE measurements for a two-terminal tandem device, such as InGaN/Si photocathode, include 1) light bias must be carefully filtered, and intensity tuned to obtain specific spectral responses and reduced nonradiative recombination, respectively, for two junctions, and 2) subcell being investigated must be current-limiting over the entire spectral range. Furthermore, the low-intensity monochromatic irradiation leads to a small photocurrent, and any discrepancy in photocathode active-area calculation will significantly under or overestimate IPCE results. Hence, to avoid errors in surface area calculations, it is useful to perform area-independent IPCE measurements, by covering the photocathode surface area with an inert mask having a well-defined opening to expose certain sample region and shield the rest of the sample area.

Further detailed electrochemical impedance spectroscopy (EIS) measurements were performed in 0.5 M H₂SO₄ under AM 1.5 G one sun illumination for both two- and three-electrode configurations for different samples to understand the charge transfer characteristics. Part (a) of FIG. 7 shows the Nyquist plots between Sample A and Sample B. The R_{ct} is calculated using the equivalent circuit models derived from these plots 25. It is noted that Sample B has the lowest R_{ct} (<150Ω cm²) at an applied bias 1.2 V vs. RHE compared to Sample A (>10,000Ω cm²). This result shows that the top p⁺-InGaN under illumination gives out photo-generated electrons, which are efficiently transferred to the electrolyte through the surface modification layers (i.e., Pt nanoparticles and Al₂O₃) and the photo-generated holes recombine with the electrons from the bottom Si without any significant losses in the tunnel junction.

As discussed previously, the Al₂O₃ passivation layer helps in improving the LSV characteristics for the double junction device. Part (b) of FIG. 7 shows the two-electrode EIS measurements at 0 V vs. IrOx for Sample B and Sample C. The semicircle arc in the lower frequency range for the double-junction photocathode with Al₂O₃ has a smaller diameter compared to the one without Al₂O₃ which is due to the reduction in charge carrier recombination, especially in p⁺-InGaN segment. Since the nanowires are coated with relatively thin ALD Al₂O₃ films, the photo-generated electrons can easily tunnel through passivation layer and participate in HER. Thus, Al₂O₃ thin-film further helps in reducing HER overpotential present in Si-based photocathodes. This Al₂O₃ film also acts as a protection layer for the nanowires and assists in improving the stability of the double-junction photocathode. This is the first use of a thin passivation layer deposited on the catalyst modified light absorber to enhance charge transfer and reduce surface recombination.

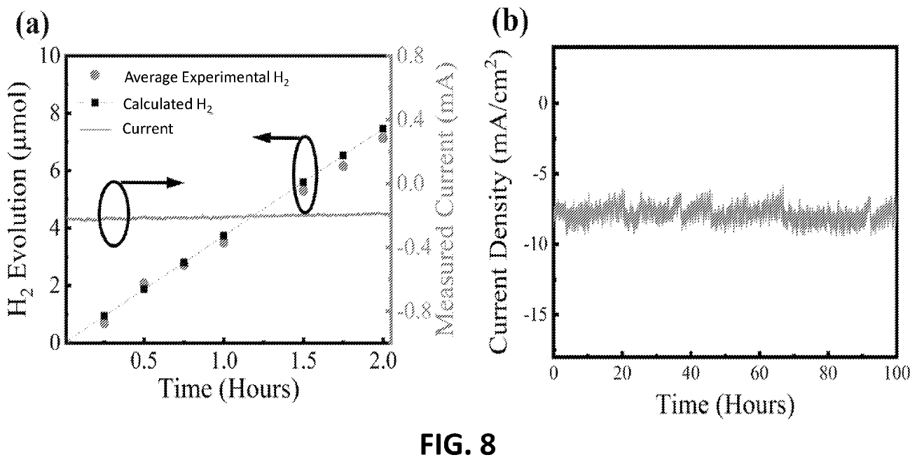

Faraday efficiency was evaluated by analyzing the H₂ generation from Sample B. Shown in Part (a) of FIG. 8, the photocurrent and H₂ evolution are simultaneously measured at 0 V vs. IrOx for a duration of 2 h in 0.5 M H₂SO₄ under AM 1.5 G one-sun illumination. The Faraday efficiency (ηFaraday) was calculated, and it is in the range of 95-100%. A long duration stability test was also conducted for Sample B at 0 V vs. IrOx in 0.5 M H₂SO₄ with 1 mM Triton X-100 surfactant under AM 1.5 G one-sun illumination. As shown in Part (b) of FIG. 8, the photocurrent density showed no degradation for a duration of 100 h. To maintain the same experimental conditions throughout the stability test, the electrolyte was changed after every 24 h. The current density varied within 10-20% of the average photocurrent density of about 8.2 mA/cm ² which corresponds to STH variation of about 9±1.5% throughout the stability experiments. The observed fluctuations in photocurrent are due to the changes in the potential of the counter electrode at 0 V vs. IrOx. This high stability at STH of about 10%, as shown in Part (a) of FIG. 3, is the longest stability reported for any photoelectrodes including III-V photoelectrodes in a two-electrode configuration.

The structural analysis after 100 h experiments is confirmed by SEM studies. SEM imaging showed that the nanowires had no changes in dimensions (length of about 600-700 nm and diameter of about 80 nm) and coverage over the Si surface compared to those taken before stability testing, shown in Part (a) of FIG. 4. X-ray diffraction measurements showed nearly identical peak positions at about 34.5° for the samples before and after stability test. Moreover, XPS measurements after stability test revealed Pt4f and Al2p peaks at 70.5° and 74.1°, respectively. The above measurements confirmed the presence of Al₂O₃ protection layer and Pt nanoparticles on InGaN nanowires after long-term stability test.

To date, the major challenges for unassisted photoelectrochemical water splitting include: (i) design and synthesis of tandem photoelectrodes, (ii) STH efficiency and stability of the photoelectrodes, and (iii) manufacturing cost and scalability of the photoelectrodes. As discussed earlier, III-V compound semiconductor multi-junction photoelectrodes (see Part (a) of FIG. 3) have achieved high efficiency but they have been plagued by poor stability and high material synthesis cost. The reasons for the instability of III-V photoelectrodes in electrolytes (see Part (a) of FIG. 3) include photocorrosion of the light absorber, pinholes in passivation layers, and insufficient co-catalyst coverage over the light absorber. It is evident that Al₂O₃/Pt/p⁺-InGaN/TJ/n⁺-p Si double junction photocathode can sustain high STH value of >10% and stability of 100 h, due to the N-terminated nanowires which have nearly perfect single wurtzite structure with negligible defects or dislocations. Due to the unique polarization induced tunnel junction embedded or otherwise incorporated in the nanowires, the charge carriers from the top p⁺-InGaN cell (photo-generated holes) readily tunnel and recombine with charge carriers (photo-generated electrons) from bottom Si subcell in the tunnel junction (see Part (c) of FIG. 3, FIG. 4, and FIG. 5). One of the limitations for this structural design, however, is the surface recombination at the top p⁺-InGaN segment. As shown in Part (b) of FIG. 7, there are some surface recombination sites at Pt/p⁺-InGaN interface, which give rise to a lower J, poor fill factor, higher Rₛ values, and sensitivity to device fabrication/synthesis conditions. Depositing a thin Al₂O₃ layer on the nanowire surface helps in reducing the surface recombination, which acts as an efficient tunneling layer for electrons from Pt/p⁺-InGaN to the electrolyte and further protects the nanowire against corrosion. Due to the efficient InGaN/Si photocathode design and Al₂O₃ protection layer, the device is capable of performing unassisted water splitting. The design and epitaxy of In-rich InGaN (with bandgap of about 1.8 eV) may be optimized or otherwise modified to provide a path to achieve STH>15%.

The high stability for Al₂O₃/Pt/p⁺-InGaN/TJnanowires/n⁺-p Si photocathode is also attributed to the stability of the III-nitride nanowires. Group III-nitrides have strong ionic bonds compared to other III-V semiconductors, with surface states bunched near the band edges, which make them resistant against corrosion in different electrolytes. The MBE grown III-nitrides may have N-termination not only on their top c-plane but also along the nonpolar sidewalls. Such N-terminated nanowires experimentally demonstrated high stability of >500 h under photocatalytic water splitting conditions with no additional protection layers and >3,000 h under PEC water splitting conditions under three-electrode measurements. Previous studies show that N-terminated InGaN nanowires on non-planar Si wafers, without any additional protection layer, can achieve high stability of about 30 h with high J of about 12 mA/cm² at 0 V vs. RHE in 0.5 M H₂SO₄ under AM 1.5 G one-sun illumination. Therefore, p⁺-InGaN nanowires are stable in acidic solution and can protect the underlying Si wafer against photo-corrosion which makes this double-junction photocathode a viable option for large-scale implementation of high-efficiency PEC water splitting.

In conclusion, a new class of InGaN/Si based double-junction photoelectrodes is disclosed, which can achieve relatively efficient, stable, unassisted PEC water splitting. The MBE grown InGaN tunnel junction nanowires on Si have high-crystalline quality, large surface area, and N-termination on both polar and non-polar side faces, which protects against photo-corrosion for the entire structure without compromising the PEC performance. Impedance studies further showed the importance of top p⁺-InGaN segment, tunnel junction and surface modifications in improving electron extraction and reducing surface recombination. The Al₂O₃/Pt/p⁺-InGaN/TJ/n⁺-p Si photocathode exhibits a maximum photocurrent density of about 8.4 mA/cm² at 0 V vs. IrOx under AM 1.5 G one-sun illumination in 0.5 M H₂SO₄. The disclosed photoelectrodes use industry-ready materials to achieve highly efficient and stable unassisted solar water splitting for low-cost H2 production.

Further details regarding the examples depicted in FIGS. 3-8 are now provided.

FIG. 3. Comparison of state-of-the-art photoelectrodes and design and performance prediction of InGaN/Si double-junction photocathode. Part (a) shows a graphical representation of stability and solar-to-hydrogen (STH) efficiency for previously reported semiconductor photoelectrodes measured under AM 1.5 G one sun illumination. Non-III-V semiconductor photoelectrodes: 1. this work, 2. BiVO₄∥Fe₂O₃/Si photoanode, 3. WO₃/BiVO₄ photoanode, 4. Co-Ci dual doped BiVO₄/1J perovskite photoanode, 5. Co-Pi Mn doped Fe₂O₃-1J perovskite photoanode, 6. Co-Pi Gradient W:BiVO₄/a:Si photoanode, and 7. 3J a-Si Co/NiMoZn photoanode. III-V semiconductor photoelectrodes: 8. Rh—TiO₂—GaInP—/GaInAs photocathode, 9. PtRu—GaInP/GaInAs photocathode, 10. Pt-metal/n⁺p GaAs & IrOx-metal/p⁺n GaAs, 11. Rh/AlInP—GaInP/GaInAs photocathode, 12. Ni—TiO₂/GaInP/GaAs photoanode, and 13. Pt/GaInP₂/GaAs photocathode. Part (b) shows a theoretical J-V simulation of an ideal In_{0.46}GaN_{0.64}/Si and In_{0.32}Ga_{0.68}N/Si tandem photocathode under AM 1.5 G one-sun illumination. Part (c) shows a schematic of InGaN nanowire arrays on Si substrate after Pt and Al₂O₃ deposition. The right-side schematic is the cross-sectional view of nanowire and Si substrate showing light absorption by the p⁺-InGaN and Si, subsequent electron transfer from Si wafer to n⁺-InGaN, charge carrier recombination in the tunnel junction and proton reduction on Al₂O₃/Pt covered p⁺-InGaN nanowires.

FIG. 4. Structural and optical properties of as grown and surface modified InGaN nanowires. Part (a) shows a 45° tilt SEM image of as-grown p⁺-InGaN nanowires with tunnel junction on Si wafer. Part (b) shows a room-temperature photoluminescence spectrum of as-grown p⁺-InGaN nanowires in the best PEC performing region of the wafer. Part (c) shows a band-diagram of the p⁺-InGaN/TJ/n⁺-p Si photocathode showing charge carrier generation in Si and p⁺-InGaN, and charge extraction from p⁺-InGaN. The top p⁺-InGaN subcell (best PEC performing region) absorbs photons with an energy (hv) of about 2.2 eV, or higher, and the bottom Si subcell absorbs photons passing through the top subcell but with an energy (hv) greater than the bandgap of Si. The band diagram was drawn assuming nearly constant In incorporation throughout the nanowire. Part (d) shows XPS measurements of Al₂O₃/Pt/p⁺-InGaN/TJ nanowires/n⁺-p Si photocathode for Pt4f and Al2p.

FIG. 5. Structural characterization of surface modified InGaN nanowire. Part (a) shows a schematic of single nanowire with Pt and Al₂O₃. Part (b) shows a STEM-HAADF image of top p⁺-InGaN segment. Part (c) shows a bright Field STEM image of tunnel junction region. The photogenerated holes from top p⁺-InGaN and electrons from bottom n⁺-InGaN/Si recombine in the tunnel junction indicated as shown in Part (c) of FIG. 3. Part (d) shows STEM-HAADF and EELS elemental mapping showing Pt and Al₂O₃ on the nanowire sidewall as shown in Part (a) of FIG. 3.

FIG. 6. Photoelectrochemical performance of surface modified InGaN/Si double-junction photocathode. Part (a) shows a three-electrode linear scan voltammogram (LSV) of Sample B and Sample A in 0.5 M H₂SO₄ under AM 1.5 G one sun illumination and dark condition (dashed curve) scan range between 2.4 V to 0.3 V vs. RHE. Part (b) shows a chopped J-V curve of Sample B under dark and AM 1.5 G one-sun illumination. The photocathode sample area is 0.025 cm².

FIG. 7. Impedance spectroscopy of surface modified InGaN/Si double-junction photocathode. Part (a) shows Nyquist plots of Sample B and Sample A in 0.5 M H₂SO₄ at 1.2 V vs. RHE under AM 1.5 G one sun illumination. Part (b) shows Nyquist plots of Sample B and Sample C in 0.5 M H₂SO₄ at 0 V vs. IrOx under AM 1.5 G one sun illumination.

FIG. 8. Hydrogen evolution and stability measurements of surface modified InGaN/Si double-junction photocathode. Part (a) depicts H₂ generation for Sample B at 0 V vs. IrOx under AM 1.5 G one-sun illumination in 0.5 M H₂SO₄ for 2 h. Part (b) depicts long-term stability measurements for Sample B at 0 V vs. IrOx in 0.5 M H₂SO₄ under AM 1.5 G one-sun illumination.

Further details regarding example methods of fabricating the photoelectrodes are now provided.

Growth of p⁺-InGaN/Tunnel Junction Nanowires on n⁺-p Si.

In this example, InGaN nanowire arrays are grown (see Part (b) of FIG. 3) on n⁺-p Si substrates 1 using a Veeco GEN II radio-frequency plasma-assisted molecular beam epitaxial growth system. Before loading into the MBE chamber, the n⁺-p Si substrate is cleaned with acetone and methanol to remove any organic contaminants. Subsequently, Si substrate is immersed in 10% buffered hydrofluoric acid to remove native oxide. The nanowires are formed spontaneously under nitrogen-rich conditions without using any external metal catalyst on the Si substrate. The growth conditions include a substrate temperature range of 670-675° C., a Ga beam equivalent pressure (BEP) of 6×10⁻⁸ torr, an In BEP of 5×10⁻⁸ torr, Ge cell temperature range of 1050-1080° C., Mg cell temperature range of 200-270° C., nitrogen flow rate of 1 standard cubic centimeter per minute (sccm), and plasma forward power of 420 W. The n⁺-InGaN buffer layer is initially grown on n⁺-Si side for 1 h. The tunnel junction is subsequently grown on top of the n⁺-InGaN buffer layer. It includes a p⁺⁺-InGaN and n⁺⁺-InGaN, which is used to connect the two light absorbers. The top p⁺-InGaN segment is then grown on top of the TJ. The indium incorporation may be highly non-uniform along the nanowire dimension.

### Pt Photo-Deposition.

The photocathode is put on a Teflon holder and placed in the bottom of a Pyrex chamber with a quartz window. Next, 20 μL of 0.2 M Chloroplatinic acid hydrate (99.9%, Sigma Aldrich) is used as Pt precursor, and 10 mL of CH3OH (i.e., a hole scavenger) and 50 mL of Milli-Q (about 2 MΩ) water are poured into the Pyrex chamber. The chamber is evacuated using a vacuum pump for 10 min. Then the sample is irradiated using a 300 W xenon lamp (PerkinElmer, PE300BF) for 30 min.

Al₂O₃ Deposition.

Before deposition of Al₂O₃ films, the Pt/p⁺-InGaN/TJ nanowires/n⁺-p Si photocathode is soaked in 37% HCl solution for about 2 min which is subsequently rinsed with DI water and dried with N₂ gun. Al₂O₃ thin films are deposited using a Veeco-Ultratech-Cambridge Fiji G2 ALD tool. Trimethylaluminum (TMA) and deionized water are used as the aluminum precursor and reactant, respectively. After pre-treatment with HCl solution, the Pt/p⁺-InGaN/TJ/n⁺-InGaN nanowires/n⁺-p Si photocathode is placed inside the ALD deposition chamber at a substrate temperature of 200° C. Each ALD cycle includes 900 sec preheat and 20 sec deposition. The rate of deposition is about 1 Å/cycle. The process is repeated for 20 cycles to achieve a thin film. The sample, after ALD deposition, is annealed in a rapid thermal annealing tool for 2 min under Ar gas flow. The ALD deposition temperature, and annealing temperature, in terms of PEC performance, may be optimized or otherwise modified.

### Electrode Preparation.

The Al₂O₃/Pt/p⁺-InGaN/TJ nanowires/n+-p Si photocathode is diced into smaller pieces using a diamond pen. The back contact is made by using Ga—In eutectic paste on the backside of the sample and subsequently connecting a Cu-wire on the ohmic contact by applying the silver paste. The electrical connection is then encapsulated by using epoxy by covering the sample except exposing the nanowires to eliminate any leakage currents. The epoxy (Loctite EA 615) is non-transparent for different thicknesses. Due to the non-transparent nature of the epoxy, light reflections from the epoxy near the perimeter of the sample will not significantly affect the surface area calculations.

### IrOx Counter Electrode Preparation.

IrOx counter electrodes are prepared on two substrates, including Ti and FTO. An iridium chloride precursor solution is spin-coated on the substrate, which is then followed by annealing at 400° C. for 30 min. After deposition, the substrate is mounted on Cu wire and encapsulated with epoxy on a glass rod. The dimensions of the electrodes are 3.5 cm×0.8 cm.

The nanowires are grown using spontaneous catalyst-free MBE growth technique under nitrogen-rich conditions. The MBE substrate heater has a temperature gradient, which leads to different band gaps (varied Indium incorporation) from one region to another within the MBE grown wafer. Due to the low sticking coefficient of Indium atoms, at lower substrate temperatures, more Indium gets incorporated, which gives rise to lower bandgap (or longer wavelength). The MBE growth parameters are tuned by growing the InGaN nanowires at a relatively high temperature with high Indium flux to obtain good crystalline quality InGaN nanowires with reduced phase separation and less surface defects across the wafer.

Further details regarding the manner in which the disclosed photoelectrodes are capable of stable operation is provided. For instance, in examples involving GaN nanowires or other nanostructures, the semiconductor substrate is protected from corrosion by the nanostructures. For example, a nitrogen-based (e.g., N-terminated) surface of the nanostructures provides protection, as described above, and further addressed below. The stability of the photoelectrodes is thus improved, rather than limited by, the nanostructures. Further details regarding the long term stability of such semiconductor photoelectrodes is now provided.

Improving the stability of semiconductor materials is one of the major challenges for sustainable and economic photoelectrochemical water splitting. N-terminated GaN nanostructures provide a practical protection layer for high efficiency but unstable Si and III-V photoelectrodes, due to their near-perfect conduction band-alignment, which enables efficient extraction of photo-generated electrons, and N-terminated surfaces, which protects against chemical and photo-corrosion. As described below, one example of a photocathode with Pt-decorated GaN nanostructures on a n⁺-p Si substrate exhibited ultrahigh stability of 3000 h (i.e., over 500 days for usable sunlight at about 5.5 hours per day) at a large photocurrent density (>35 mA/cm²) in a three-electrode configuration under AM 1.5 G one-sun illumination. The measured applied bias photon-to-current efficiency of 11.9%, with an excellent onset potential of about 0.56 V vs. RHE, is one of the highest values reported for a Si photocathode under AM 1.5 G one-sun illumination. Based on the examples described herein, the stability of semiconductor photoelectrodes for PEC water splitting is no longer limited by the light absorber, but rather by co-catalyst particles.

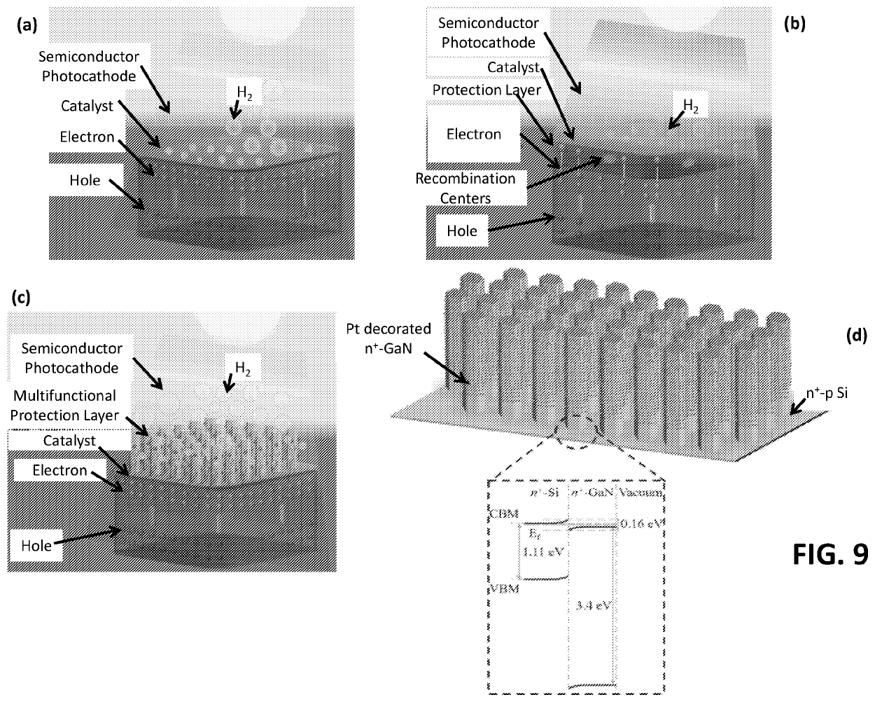

In each of the photoelectrodes schematically depicted in FIG. 9, photogenerated electrons and holes are separated, and electrons are transferred to the catalyst active sites for proton reduction. The configuration shown in Part B of FIG. 9 has a surface protection scheme that has the semiconductor photoelectrode covered with a conventional thick protection layer and a catalyst layer. The device efficiency is often compromised with the use of such surface protection, due to parasitic light absorption, reduced charge carrier separation and extraction, and/or undesirable charge carrier recombination (recombination centers shown separately), which leads to lower H₂ production.

To achieve both high efficiency and long-term stability, a multi-functional surface protection scheme may be used, an example of which is schematically shown in Parts C and D of FIG. 9. Such a protection scheme may offer both robust surface protection and significantly improved optical, electrical, and photoelectrochemical performance. As described herein, the disclosed photoelectrodes may integrate Pt-decorated N-rich GaN nanostructures with a n⁺-p Si wafer or other substrate. The N-terminated surfaces of GaN protect the underlying Si absorber against photocorrosion and oxidation. Unique to the GaN/Si heterointerface is that the conduction band edges are near-perfectly aligned, thereby leading to efficient extraction of photo-generated charge carriers (electrons) from the underlying Si absorber, schematically shown in Part D of FIG. 9. In one example of the surface protection scheme, Si photocathodes exhibited an ultrahigh stability of 3,000 h with a stable photocurrent density between 37-38 mA/cm² in 0.5 M H₂SO₄ under AM 1.5 G one sun illumination in a three-electrode configuration, which, to the best of our knowledge, is the longest stability ever measured for any photoelectrode materials for H₂ production in a half-cell configuration. The best performing platinized n⁺-GaN nanowires/n+-p Si photocathode showed excellent onset potential (Vₒₙ) of about 0.56 V vs. RHE with high photocurrent density of about 37 mA/cm² and a high applied bias photon-to-current efficiency (ABPE) of 11.9%. The device stability is further exhibited by using atomic force microscopy (AFM) measurements. The utilization of GaN and Si, two most produced semiconductor materials in the world, to realize high efficiency and highly stable photoelectrochemical water splitting provides a scalable and practical approach for solar fuel production.

The stability testing establishes that the protection layer of the photoelectrode shown in Parts C and D of FIG. 9 is inherently stable in the electrolyte, which provides long-term stability and also significantly enhances the light absorption, charge carrier separation, and charge carrier extraction, and further reduces surface recombination, thereby leading to enhanced efficiency. The Pt/n⁺-GaN nanowires on n⁺-p Si photocathode also benefit from the negligible conduction band offset between n⁺-GaN and n⁺-Si, enabling efficient charge carrier extraction, as shown by the band-diagram of Part D of FIG. 9.

In the examples described and evaluated below, n⁺-GaN nanowires were grown on n⁺-p Si wafer using a Veeco GEN II molecular beam epitaxial (MBE) system equipped with a radio frequency plasma-assisted nitrogen source. Illustrated in Part D of FIG. 9, the conduction band minimum (CBM) for n⁺-GaN is nearly perfectly aligned with that of n⁺-Si. Consequently, photo-generated electrons from the n⁺-p Si substrate are efficiently extracted by the GaN nanowires, e.g., with negligible resistivity, even in cases in which a relatively thick GaN protection layer is employed, which is in direct contrast to the undesirable high resistivity associated with other, relatively thick, conventional protection schemes.

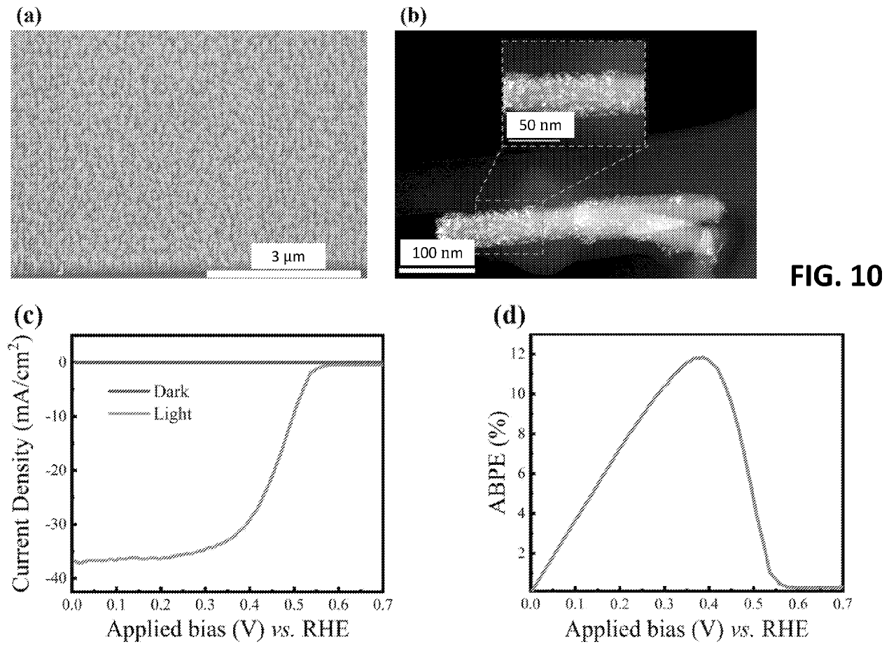

Part A of FIG. 10 shows a scanning electron microscope (SEM) image of an example of the as grown nanowires, which are vertically aligned to the Si substrate, with an average length about 400 nm and a diameter of about 40 nm, although other sizes may be used. The photoelectrode may be prepared, including photo-deposition of Pt nanoparticles, as described herein. The structural characterization after Pt photo-deposition for the samples was performed using scanning transmission electron microscopy (STEM). Part B of FIG. 10 shows the distribution of Pt nanoparticles around GaN nanowires. Part C of FIG. 10 shows the linear scan voltammogram (LSV) of Pt-decorated n⁺-GaN nanowires on n⁺-p Si photocathode under AM 1.5 G one sun illuminated (light) and dark conditions. The Pt/n⁺-GaN nanowires/n⁺-p Si photocathode showed excellent performance with an onset potential (Vₒₙ) of about 0.56 V vs RHE and high photocurrent density of about 37 mA/cm² under AM 1.5 G one-sun illumination in 0.5 M H₂SO₄. Shown in Part D of FIG. 10, the maximum ABPE for the Pt/n⁺-GaN nanowires/n⁺-p Si photocathode is 11.9% at 0.38 V vs. RHE under AM 1.5 G one sun illumination, which is one of the best reported values for Si photocathodes. For the stability tests (both under dark and light), photoelectrode samples with ABPE≥10% and J at 0 V vs. RHE between 37-38 mA/cm² were selected.

Before starting the stability experiments, the photoelectrode was thoroughly rinsed with distilled water and dried with a nitrogen N₂ gun. The photoelectrode was then placed in 0.5 M H₂SO₄ inside the PEC chamber, and the stability experiment was conducted at a constant applied potential of 0 V vs. RHE under AM 1.5 G one-sun illumination. Stability of about 113 hours had previously been achieved. Further stability testing, however, showed performance degradation arising from considerable loss of Pt nanoparticles on the GaN nanowire surface, which explained the poor onset potential. The photoelectrode material itself, including GaN and Si, showed no sign of degradation.

To study the intrinsic stability of the GaN/Si photocathodes, a catalyst regeneration process was implemented. The process was performed after approximately every 24 hours of PEC experiments. After each catalyst regeneration, the J-V characteristics were measured under both dark and AM 1.5 G one-sun illumination and were compared to the 0th hour J-V characteristics. Then the experiment was resumed for the next cycle of stability test and catalyst regeneration. After every 24 h experiment, the electrolyte was replaced with a fresh solution to maintain a constant pH of about 0 for all the runs and to reduce possible carbonaceous contaminations from epoxy.

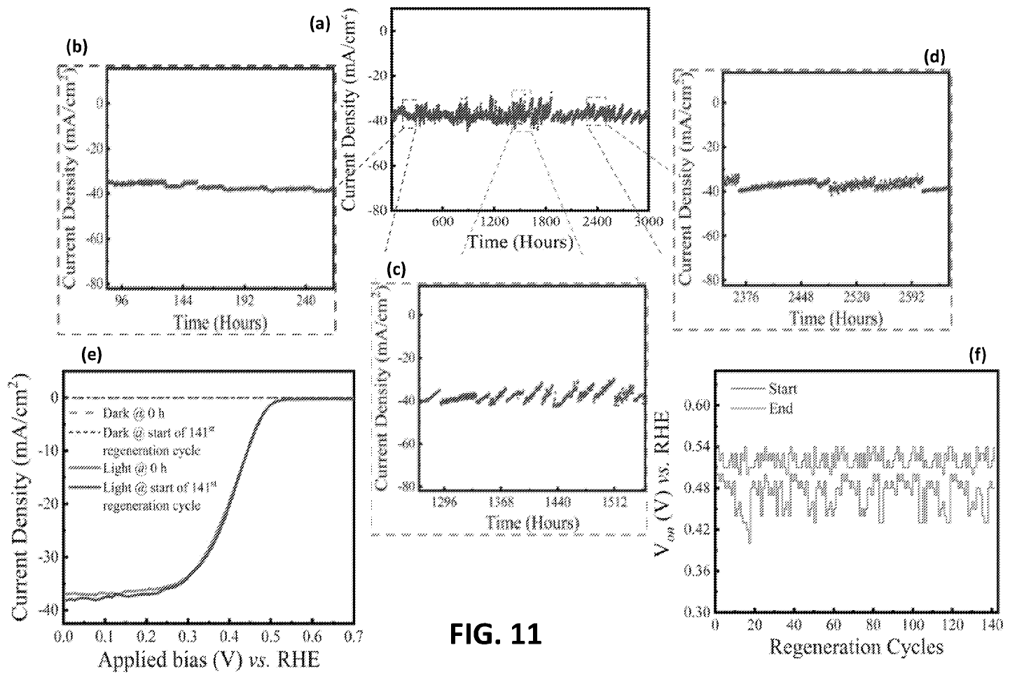

Part A of FIG. 11 shows the photocurrent density variation over the entire duration of 3,000 hours for Pt/n⁺-GaN nanowires/n⁺-p Si photocathode under AM 1.5 G one-sun illumination at 0 V vs. RHE in 0.5 M H₂SO₄. As shown in Part B of FIG. 11, for the 80-264 hour runs, i.e., between the 4th and 12th regeneration cycles, the photocurrent density varied between 36-40 mA/cm², which is within ±10% of the average J₀ value measured at 0 V vs. RHE. Part C of FIG. 11 shows that the variations in J increased to about ±20-25% from 1270 to 1539 hours, i.e., between 59th and 73rd regeneration cycles. These variations are mainly due to an unexpected epoxy meltdown, a malfunctioning of potentiostat (due to electrical fluctuations in the building) and a poor backside contact. In these cases, the experiments were stopped to troubleshoot these issues, which led to an increase in the number of regeneration cycles. The experimental problems were addressed during the subsequent runs by frequently redoing the backside contact after every 100-120 hours of runs and carefully monitoring the potentiostat during the cycles. Part D of FIG. 11 shows that the photocurrent variations for the 2350-2640 hour runs (between the 113th and 125th regeneration cycles) is within ±10% of the J₀. Despite photocurrent variations, the J-V characteristics at the start of the 141st regeneration cycle, i.e., after the 3008 hour run with Pt redeposition, are nearly the same as the J₀ curve at the start of the experiments (see Part E of FIG. 11), which implies that the GaN nanowires remain intact on the Si surface. Furthermore, Part F of FIG. 11 shows the variation of Vₒₙ for each regeneration cycle at the start and end of each cycle. The slight reduction of Vₒₙ at the end of each regeneration cycle is due to the loss of some Pt nanoparticles as described earlier. The catalyst regeneration, at the start of each cycle, helps in immediately recovering the Vₒₙ for the LSV curves.

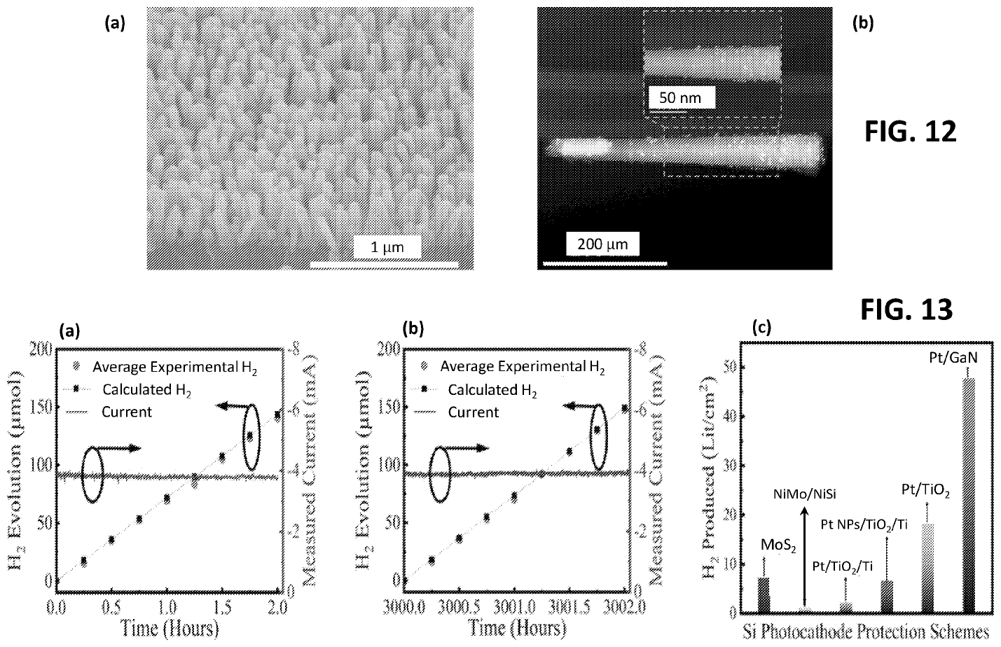

Detailed structural characterization was further performed after the 3,000 hour experiments. An SEM image in Part A of FIG. 12 shows that there is virtually no change in nanowire morphology compared to the as grown samples. Illustrated in Part B of FIG. 12, an STEM image shows that the nanowire length is about 400 nm and the diameter is about 40 nm, which are nearly identical to those shown in Part B of FIG. 10. No apparent etching of the nanowire surface was observed. The inset in Part B of FIG. 12 shows the reduction of Pt nanoparticles over the nanowire compared to Part B of FIG. 10. Due to the Pt nanoparticles falling-off, the J-V curve immediately at the end of the 140th regeneration cycle degraded somewhat. By doing Pt regeneration at the start 141st regeneration cycle, the J-V characteristics were restored to the 0th hour curves, which clearly shows that GaN nanowires are still protecting the Si photocathode and the GaN-protected Si photocathode can last significantly longer than 3,000 hours. Moreover, the dark currents before and after Pt regenerations for the 46th, 96th, and 140th regeneration cycles were nearly the same as the 0th hour dark current. The ABPE for the 0th hour and at the start of the 141st regeneration cycles under AM 1.5 G one-sun illumination was found to be about 10%. These results are also consistent with the nearly identical X-ray diffraction measurements performed on the sample before and after the stability testing. The dissolved Ga and Pt elements in the electrolyte were analyzed using inductively coupled plasma mass spectroscopy (ICP-MS). ICP-MS results for different runs showed dissolved Ga concentrations of 15-20 nmol and Pt concentrations of 1-5 nmol, considering an error bar about 10% in the measurements. These results clearly show that the GaN nanowires remain stable throughout the course of the stability test, which agrees well with the above-mentioned STEM analysis.

The Faraday efficiency was also evaluated by analyzing the H₂ generation from a Pt/n⁺-GaN nanowires/n⁺-p Si photocathode between the 0-2 hour period and the 3000-3002 hour period. As shown in Part A of FIG. 13, the photocurrent and H₂ evolution are simultaneously measured for the sample between the 0-2 hour period at 0 V vs. RHE for a duration of 2 h in 0.5 M H₂SO₄ under AM 1.5 G one sun illumination. Similarly, H₂ evolution experiment was carried out for the sample between the 3000-3002 hour period (shown in Part B of FIG. 13) under the same conditions. In both cases, the Faraday efficiency is nearly 100%, considering that there is an error bar about 10% of H₂ sampling. Given the nearly identical LSV curves measured at 0 hour and 3000 hours, it is reasonably concluded that the GaN/Si photocathode can drive solar water splitting with stability over 3,000 hours.

The total charge passed during the 3000 hour light experiment for Pt/n⁺-GaN nanowires/n⁺-p Si photocathode was 410,400 C/cm² by considering an average saturation photocurrent density of about 38 mA/cm² for 3,000 hours. The platinized n⁺-GaN nanowires/n⁺-p Si photocathode over 3,000 hours of operation had the same amount of charge passed during >1.5 years of outdoor operation under AM 1.5 G one-sun conditions with a solar capacity of 20%. As the projected operation is a lower limit on the actual stability of Pt/n⁺-GaN nanowires/n⁺-p Si, accelerated long-term stability tests are implemented with temperature and light intensity variations to precisely identify the degradation/corrosion mechanisms. Furthermore, Part C of FIG. 13 shows the amount of H₂ production (in Lit/cm²) at standard temperature and pressure (STP) conditions for some of the best reported long-term stability photocathodes over the entire duration of the stability experiments. Compared to these photocathodes, the platinized n⁺-GaN nanowires/n⁺-p Si photocathode has the highest H₂ production of >45 Lit/cm². These results, combined with the fact that GaN and Si are industry established materials, suggest the scalability and economic viability of the disclosed photocathode system for large-scale implementation of PEC water splitting. Recent studies show that the PEC characteristics for n⁺-GaN nanowires/n⁺-p Si photocathode are further improved by using controllable Pt loading amounts through PEC photo-deposition. In-situ catalyst regeneration may be used in other cases.

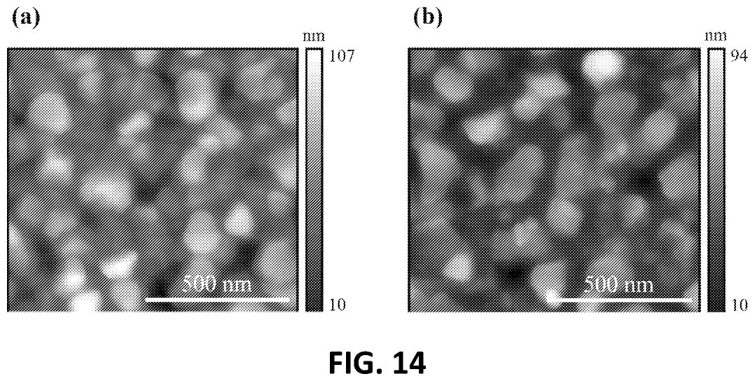

Atomic force microscope (AFM) measurements on GaN-protected Si photocathodes before and after chronoamperometry testing were also performed to compare the morphology change due to the photoelectrochemistry. Because such AFM measurements are performed on planar surfaces, nearly coalesced GaN nanostructures with a quasi-planar morphology were used in this experiment. Shown in Parts A and B of FIG. 14, no change in surface morphology was observed for 10 hour of reaction, further confirming that GaN is intrinsically stable in harsh photocatalysis conditions. Studies were also performed by varying the thickness of the GaN surface protection layer. The measured photocurrent densities were nearly the same for the samples studied, which is consistent with the near-perfect conduction band alignment between GaN and Si.

The underlying mechanism for the unprecedentedly ultrahigh stability of GaN protected Si photocathode is described. Firstly, wurtzite GaN nanowires grown on Si wafer are nearly free of dislocations due to the efficient surface strain relaxation, and have strong ionic bonds which lead to bunching of surface states near the band edges. The GaN nanostructures of the disclosed photocathodes may have N-termination, both on the top c-plane surface and also for the lateral nonpolar surfaces, which protects against photocorrosion and oxidation. There may also be a thin GaN layer beneath the nanowires which protects the Si from the formation of insulating oxide and passivates the surface states to prevent charge carrier recombination. Moreover, due to the negligibly small conduction band offset between Si and GaN, there is virtually no loss in charge carrier extraction. As such, the GaN nanostructures protect the underlying Si surface against photo-corrosion with enhanced charge carrier extraction kinetics and better light absorption. The Pt/GaN interface further improves the charge carrier extraction compared to Pt/Si and thereby enhances the overall stability of the photocathode.

As described above, Pt/n⁺-GaN nanowires/n⁺-p Si photocathodes exhibit both high efficiency and long-term stable operation in a three-electrode configuration. The GaN nanostructures significantly enhance the performance of Si photocathodes (e.g., achieving high photocurrent density of about 38 mA/cm² and ABPE of about 11.9%) and further provide extremely robust protection of the Si surface for over 3000 hours (>500 days) without any performance degradation, e.g., without any loss of photocurrent, onset potential, or efficiency. In other cases, the disclosed photocathodes may be utilized in a two-electrode configuration. The PEC platform provided by the disclosed photocathodes utilize the two most produced semiconductors, i.e., Si and GaN, thereby laying a solid foundation for realizing practical PEC water splitting devices and systems that are efficient, stable, and of low cost.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate having a surface;
an array of conductive projections supported by the substrate and extending outward from the surface of the substrate;
a plurality of catalyst nanoparticles disposed over the array of conductive projections; and
an oxide layer covering the plurality of catalyst nanoparticles and the array of conductive projections;
wherein the oxide layer has a thickness on the order of a size of each catalyst nanoparticle of the plurality of catalyst nanoparticles.

2. The device of claim 1, wherein the thickness of the oxide layer falls within a range of about 1 nm to about 2 nm.

3. The device of claim 1, wherein the size of each catalyst nanoparticle of the plurality of catalyst nanoparticles falls in a range from about 2 nm to about 3 nm.

4. The device of claim 1, wherein the oxide layer comprises aluminum oxide.

5. The device of claim 1, wherein the oxide layer conformally covers the plurality of catalyst nanoparticles and the array of conductive projections.

6. The device of claim 1, wherein:
each conductive projection of the array of conductive projections comprises a plurality of indium gallium nitride (InGaN) segments;
the plurality of InGaN segments comprises a first segment having a compound semiconductor composition configured for photogeneration of charge carriers, and second and third segments configured to establish a tunnel junction;
the substrate comprises a plurality of silicon layers; and
the plurality of silicon layers are doped to establish a junction for charge carriers photogenerated in the substrate.

7. The device of claim 6, wherein the plurality of InGaN segments further comprises a fourth segment between the tunnel junction and the substrate.

8. The device of claim 1, wherein:
each conductive projection of the array of conductive projections has a semiconductor composition; and
the semiconductor composition of each conductive projection of the array of conductive projections is terminated with nitrogen along surfaces of the conductive projection.

9. The device of claim 1, wherein each conductive projection of the array of conductive projections comprises indium gallium nitride doped with magnesium. The device of claim 1, wherein each conductive projection of the array of conductive projections comprises a nanowire.

11. The device of claim 1, wherein each catalyst nanoparticle of the plurality of catalyst nanoparticles comprises platinum.

12. A method of fabricating a device, the method comprising:
providing a substrate having a surface;
growing an array of nanowires on the surface of the substrate such that each nanowire of the array of nanowires extends outward from the surface of the substrate, each nanowire of the array of nanowires having a semiconductor composition;
depositing a plurality of catalyst nanoparticles across the array of nanowires; and
covering the plurality of catalyst nanoparticles and the array of nanowires with an oxide layer;
wherein the oxide layer has a thickness on the order of a size of each catalyst nanoparticle of the plurality of catalyst nanoparticles.

13. The method of claim 12, wherein covering the plurality of catalyst nanoparticles and the array of nanowires comprises depositing aluminum oxide via atomic layer deposition.

14. The method of claim 12, wherein depositing the plurality of catalyst nanoparticles comprises implementing a photo-deposition procedure with platinum. The method of claim 12, wherein growing the array of nanowires comprises implementing a molecular beam epitaxy (MBE) procedure with N-rich conditions.

16. The method of claim 12, wherein:
growing the array of nanowires comprises adjusting a parameter of the MBE procedure to vary an indium incorporation level in the semiconductor composition such that each nanowire of the array of nanowires comprises a plurality of indium gallium nitride (InGaN) segments;
the plurality of InGaN segments comprises a first segment configured to absorb visible light, and second and third segments configured to establish a tunnel junction;
the substrate comprises a plurality of silicon layers; and
the plurality of silicon layers are doped to establish a junction.

17. A device comprising:
a substrate comprising a plurality of semiconductor layers and a surface, the plurality of semiconductor layers being doped to establish a junction for charge carriers photogenerated in the substrate; and
an array of nanostructures supported by the substrate and extending outward from the surface of the substrate, each nanostructure of the array of nanostructures comprising a plurality of semiconductor segments, the plurality of semiconductor segments comprising:
a first segment having a semiconductor composition configured for photogeneration of charge carriers; and
second and third segments configured to establish a tunnel junction;
wherein a surface of the plurality of semiconductor segments comprises nitrogen.

18. The device of claim 17, wherein the surface of the plurality of semiconductor segments is nitrogen-terminated.

19. The device of claim 17, further comprising a plurality of catalyst nanoparticles disposed over the array of nanostructures.

20. The device of claim 19, further comprising an aluminum oxide layer covering the plurality of catalyst nanoparticles and each nanostructure of the array of nanostructures.

21. The device of claim 20, wherein the aluminum oxide layer has a thickness on the order of a size of each catalyst nanoparticle of the plurality of catalyst nanoparticles.

22. The device of claim 17, wherein the plurality of semiconductor segments further comprises a fourth segment between the tunnel junction and the substrate.

23. The device of claim 17, wherein each semiconductor segment of the plurality of semiconductor segments comprises InGaN.

24. A method of fabricating a device, the method comprising:
forming a structure on a semiconductor substrate of the device, the structure having a surface configured to facilitate a reaction; and
forming a layer on the surface, the layer comprising nitrogen.

25. The method of claim 24, wherein forming the layer comprises implementing a reaction to form the layer spontaneously.

26. The method of claim 24, wherein forming the layer comprises depositing the layer on the structure.

27. The method of claim 24, wherein forming the structure comprises depositing a layer on a substrate, the layer being configured to facilitate the reaction.

28. A device comprising:
a semiconductor structure having a surface;
a catalyst arrangement disposed on the surface; and
a conformal protection layer covering the catalyst arrangement;
wherein the conformal protection layer has a thickness that allows charge carrier transfer to occur at the catalyst arrangement.

29. The device of claim 28, wherein the conformal protection layer comprises an oxide.
